(19) United States
(12) Patent Application Publication
(10) Pub. No.: US 2026/0200255 A1
(43) Pub. Date: Jul. 16, 2026

(54) PAD PRINTING DEVICE, METHOD FOR PROVIDING WINDOW USING THE SAME, AND METHOD FOR PROVIDING ELECTRONIC DEVICE HAVING THE WINDOW

(71) Applicant: Samsung Display Co., Ltd., Yongin-si (KR)

(72) Inventor: JUNYOUNG KIM, Yongin-si (KR)

(21) Appl. No.: 19/426,263

(22) Filed: Dec. 19, 2025

(30) Foreign Application Priority Data
Jan. 15, 2025 (KR) 10-2025-0006143

(51) Int. Cl. B41M 1/34; B41F 17/00; B41F 31/02; H05K 5/03

(52) U.S. Cl. CPC B41M 1/34; B41F 17/001; B41F 31/02; H05K 5/03

(57) ABSTRACT

A method for providing an electronic device includes providing a glass body of a window of the electronic device, in a jig providing a pad having an ink adhered to a pressing part of the pad, and transferring the ink from the pressing part to an outer edge of the glass body by pressing the pad having the ink adhered thereto to the glass body, to form a bezel pattern of the window. Thees pressing part includes a bottom surface and a protrusion which extends from the bottom surface in a direction away from the bottom surface. The protrusion defining a protrusion surface which is curved and spaced apart from the bottom surface in the direction away from the bottom surface, the ink being adhered to the pad at the protrusion surface.

This application claims priority to Korean Patent Application No. 10-2025-0006143, filed on January 15, 2025, and all the benefits accruing therefrom under 35 U.S.C. §119, the entire contents of which are hereby incorporated by reference.

### BACKGROUND

### Field

The present disclosure herein relates to a pad printing device, a method for manufacturing (or providing) a window using the same, and a method for manufacturing an electronic device having the window.

### Description of the Related Art

Electronic devices which provide images for users include display panels which display the images, and windows disposed on the display panels. The windows protect the display panels from external impacts and scratches. In addition, the windows, which provide front surfaces of the electronic devices, directly affect designs of display devices.

### SUMMARY

Various bezel patterns may be formed on windows used in an electronic device (or display device), not only to add functions to protect the electronic device or display device, but also to add various aesthetic designs to the devices. For instance, printing pads may be used to transfer inks to edges of the windows so that the bezel patterns having certain colors are formed on the edges of the windows.

The present disclosure provides a pad printing device including a pad capable of preventing a glass from being damaged during printing a bezel pattern, a method for manufacturing (or providing) a window by using the pad printing device, and a method for manufacturing an electronic device having the window by using the pad printing device.

An embodiment of the invention provides a method for manufacturing a window, the method including disposing a glass in an accommodation groove defined in an upper surface of a jig, the glass including a transmission area and a non-transmission area surrounding the transmission area, moving a pad including a pressing part downward to adhere an ink disposed in an upper surface of a mold to a lower surface of the pressing part, positioning the pad above the jig to dispose the pad above the glass, moving the pad down toward the glass to press the glass, and removing the pad from the glass to form a bezel pattern on an edge of the glass. The lower surface of the pressing part may include a bottom surface having a plane defined by a first direction and a second direction crossing the first direction, and a protrusion surface extending from the bottom surface in a downward direction and surrounding the bottom surface when viewed on a plane. The protrusion surface may be more adjacent to the glass than the bottom surface is.

In an embodiment of the invention, a method for manufacturing a window includes providing a glass to an accommodation groove defined in an upper surface of a jig, moving a pad including a pressing part downward to adhere an ink disposed in an upper surface of a mold to a lower surface of the pressing part, moving the pad in an upward direction and a first direction to dispose the pad above the glass, moving the pad down toward the glass to press the glass, and removing the pad from the glass to form a bezel pattern on an edge of the glass. The lower surface of the pressing part may include a bottom surface, and a protrusion surface including a curved surface and surrounding the bottom surface when viewed on a plane. A height of the protrusion surface may be less than a height of the bottom surface.

In an embodiment of the invention, a method for manufacturing an electronic device includes disposing a glass in an accommodation groove defined in an upper surface of a jig, the glass including a transmission area and a non-transmission area surrounding the transmission area, moving a pad including a pressing part downward to adhere an ink disposed in an upper surface of a mold to a lower surface of the pressing part, positioning the pad above the jig to dispose the pad above the glass, moving the pad down toward the glass to press the glass, removing the pad from the glass to form a bezel pattern on an edge of the glass, and bonding the glass and a display module to each other to accommodate the glass and the display module in a case. The lower surface of the pressing part may include a bottom surface having a plane defined by a first direction and a second direction crossing the first direction, and a protrusion surface extending downward from the bottom surface and surrounding the bottom surface when viewed on a plane. The protrusion surface may be more adjacent to the glass than the bottom surface is.

In an embodiment of the invention, a pad printing device includes a mold having an upper surface in which an ink groove provided to contain an ink is defined, a jig disposed adjacent to the mold and having an upper surface in which an accommodation groove provided to dispose a glass is defined, and a pad disposed above the jig and the mold. The pad may include a body part and a pressing part extending in a downward direction from a lower surface of the body part toward the jig, and a lower surface of the pressing part may have a stepped portion.

### BRIEF DESCRIPTION OF THE FIGURES

The accompanying drawings are included to provide a further understanding of the invention, and are incorporated in and constitute a part of this specification. The drawings illustrate embodiments of the invention and, together with the description, serve to explain principles of the invention. In the drawings:

FIG. 1 is a perspective view of a pad printing device according to an embodiment of the invention;

FIG. 2 is a plan view of a pad illustrated in FIG. 1;

FIG. 3 is a cross-sectional view of a pad corresponding to line I-I' illustrated in FIG. 1;

FIG. 4 is a perspective view of an electronic device manufactured (or provided) by the pad printing device illustrated in FIG. 1;

FIG. 5 is a view illustrating a folded state of the electronic device illustrated in FIG. 4;

FIG. 6 is an exploded perspective view of the electronic device illustrated in FIG. 4;

FIG. 7 is a plan view of a rear surface of a window illustrated in FIG. 6;

FIGS. 8A to 8G are cross-sectional views for describing a method for manufacturing (or providing) the window illustrated in FIG. 6;

FIG. 9 is a view illustrating a pad according to a comparative example;

FIGS. 10A and 10B are views illustrating a pad according to a comparative example;

FIGS. 11A and 11B are views illustrating a pad according to a comparative example;

FIG. 12 is a graph for describing amounts of thickness deformations for a pad according to an embodiment of the invention and a pad according to a comparative example; and

FIG. 13 is a plan view of a glass indicating a force applied to the glass when the glass is pressed using a pad according to an embodiment of the invention.

FIG. 14 is a block diagram illustrating an electronic device according to an embodiment of the present disclosure.

FIG. 15 is a schematic view of electronic devices according to embodiments of the present disclosure.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

In this specification, it will be understood that when an element (or a region, a layer, a portion, or the like) is referred to as being related to another element such as being "on", "connected to" or "coupled to" another element, it may be directly disposed on, connected to, or coupled to the other element, or other elements may be disposed therebetween. In contrast, when an element (or a region, a layer, a portion, or the like) is referred to as being related to another element such as being "directly on", "directly connected to" or "directly coupled to" another element, no other element is disposed therebetween.

Like reference numerals or symbols refer to like elements throughout. Within the Figures and the text of the disclosure, a reference number indicating a singular form of an element may also be used to reference a plurality of the element. In the drawings, the thickness, ratio, and size of the elements are exaggerated for effectively describing the technical contents.

The terminology used herein is for the purpose of describing particular embodiments only and is not intended to be limiting. As used herein, "a", "an," "the," and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, "an element" has the same meaning as “at least one element," unless the context clearly indicates otherwise. “At least one” is not to be construed as limiting “a” or “an.” “Or” means “and/or.” The term "and/or" includes one or more combinations which may be defined by relevant elements.

It will be understood that, although the terms "first", "second", (1-1)-th, (1-2)-th, (2-1)-th, (2-2)-th, etc. may be used herein to describe various elements, the elements are not to be limited by these terms. These terms are only used to distinguish one element, component, region, layer or section from another element, component, region, layer or section. For instance, a first element, component, region, layer or section discussed below could be termed a second element, component, region, layer or section without departing from the scope of the invention. Similarly, a second element, component, region, layer or section could be termed a first element, component, region, layer or section.

In addition, the terms "below", "under", "on the lower side", "above", "over", "on the upper side", or the like may be used to describe the relationships between the elements illustrated in the drawings. These terms are relative concepts and are described on the basis of the directions indicated in the drawings.

It will be further understood that the terms "comprises, includes, has" and/or "comprising, including, having", when used in this specification, specify the presence of stated features, numbers, steps, operations, elements, components or combinations thereof, but do not preclude the possibility of the presence or addition of one or more other features, numbers, steps, operations, elements, components, and/or combinations thereof.

"About" or "approximately" as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, "about" can mean within one or more standard deviations, or within ± 30%, 20%, 10% or 5% of the stated value.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the invention will be described with reference to the accompanying drawings.

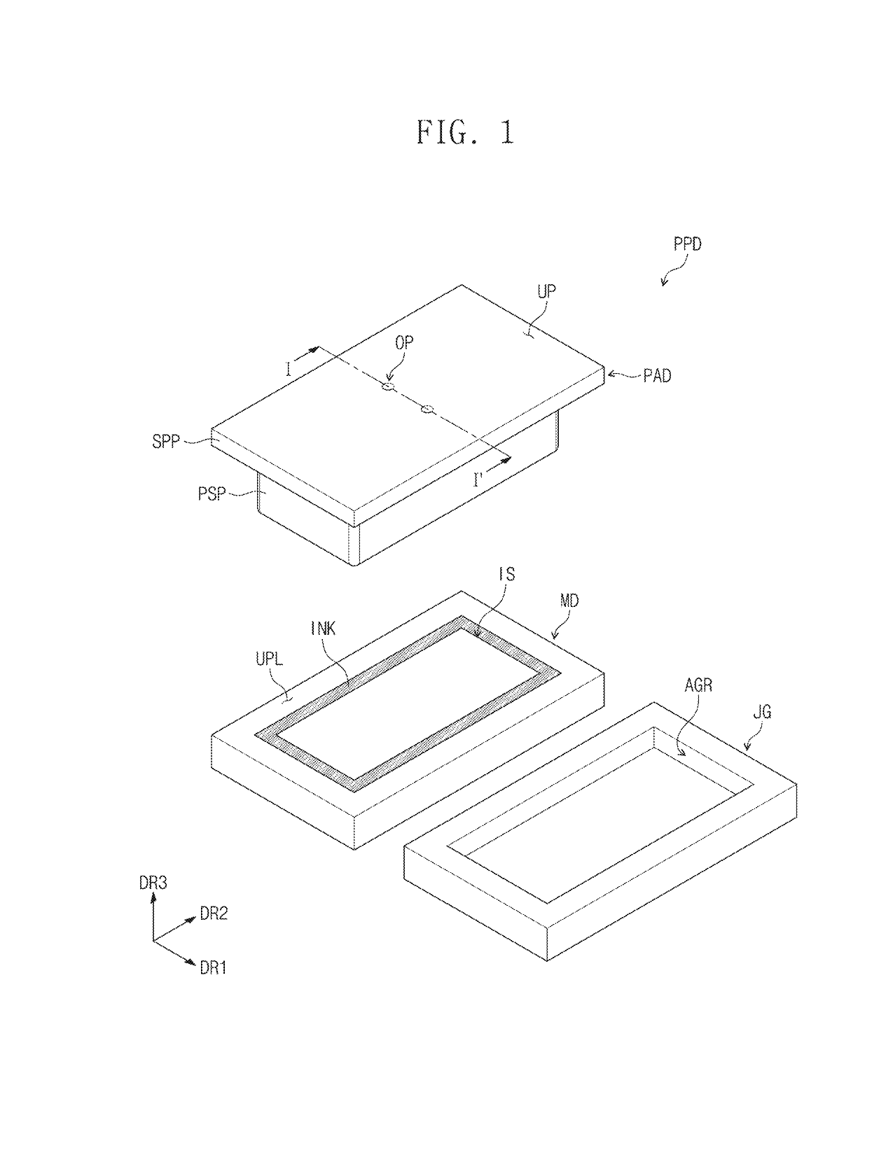

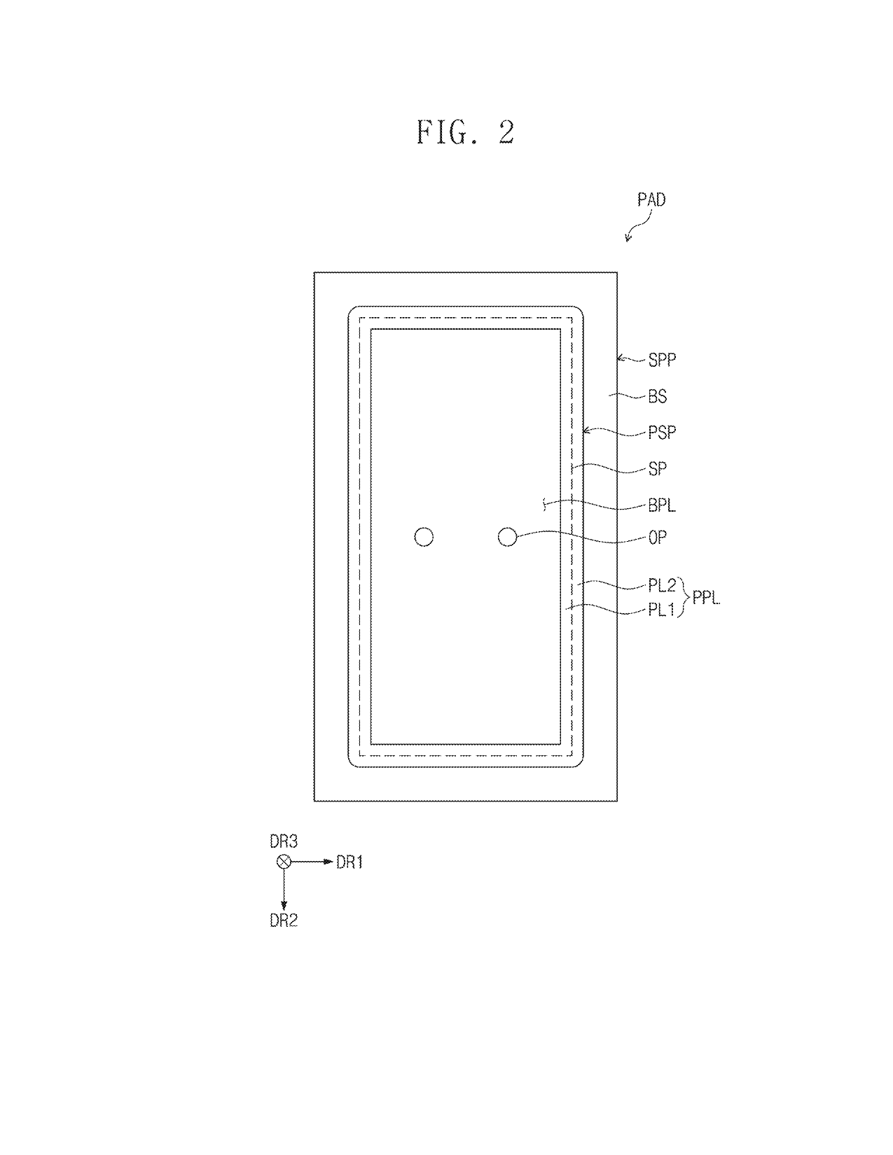

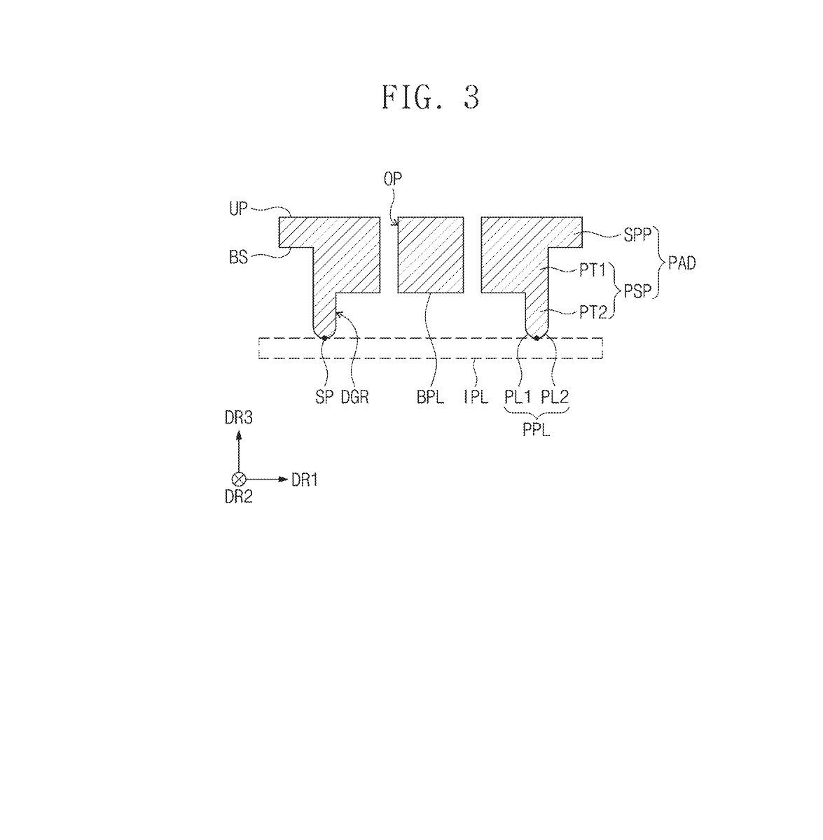

FIG. 1 is a perspective view of a pad printing device PPD according to an embodiment of the invention. FIG. 2 is a plan view of a pad PAD illustrated in FIG. 1. FIG. 3 is a cross-sectional view of a pad PAD corresponding to line I-I' illustrated in FIG. 1.

FIG. 2 illustrates a plan view of a lower surface of the pad PAD.

Referring to FIG. 1, a pad printing device PPD may include a mold MD, a pad PAD, and a jig JG. The mold MD may have a rectangular parallelopiped shape having short sides extending in a first direction DR1 and having long sides extending in a second direction DR2 which crosses the first direction DR1. However, the shape of the mold MD is not limited thereto. The mold MD may include a stainless steel (SUS) material.

The first direction DR1 and the second direction DR2 crossing each other may define a plane. Hereinafter, a direction substantially perpendicularly crossing a plane defined by the first direction DR1 and the second direction DR2 is defined as a third direction DR3. In addition, the phrase "when viewed on a plane" used herein may be defined as being in a state viewed in the third direction DR3. A thickness of the pad printing device PPD and various components or layers thereof may be defined along the third direction DR3 (e.g., a thickness direction).

The mold MD may include an upper surface UPL parallel to a plane defined by the first direction DR1 and the second direction DR2. An ink groove IS may be defined in the upper surface UPL of the mold MD. The ink groove IS may have a rectangular frame shape in the plan view. An ink INK for printing a bezel pattern BZ of a window WM to be described later may be contained in the ink groove IS. The ink groove IS may be recessed from the upper surface UPL. The ink groove IS may be open to outside the mold MD, at the upper surface UPL thereof.

Referring to FIGS. 1 to 3, the pad PAD may be disposed above the mold MD and the jig JG. The pad PAD may include an elastic body. For example, the pad PAD may include at least one of silicon and rubber.

The pad PAD may include a body part SPP as a main body and a pressing part PSP as a presser. The body part SPP may include an upper surface UP and a lower surface BS. The upper surface UP may be parallel to a plane defined by the first direction DR1 and the second direction DR2. The upper surface UP may be furthest from the mold MD and/or the jig JG. The lower surface BS may oppose the upper surface UP in the third direction DR3. The lower surface BS may be referred to as a base surface BS. A virtual line extended from the lower surface BS may be a boundary between the body part SPP and the pressing part PSP.

The pressing part PSP may extend from the base surface BS of the body part SPP. In a planar direction, such as along the first direction DR1 and/or the second direction DR2, the body part SPP may extend further than an outer sidewall of the pad PAD which is defined at the pressing part PSP. An extended portion of the body part SPP may be defined between the lower surface BS and the upper surface UP. The body part SPP and the pressing part PSP may be provided substantially as one body. As illustrated in FIG. 2, the base surface BS may surround the pressing part PSP when viewed on a plane.

The pressing part PSP may include a first portion PT1 as a first thickness portion and a second portion PT2 as a second thickness portion. A virtual boundary may be laterally defined between the first portion PT1 and the second portion PT2. The body part SPP may be considered a third thickness portion of the pad PAD. The first portion PT1 may extend from the base surface BS, in the third direction DR3.

The pad PAD may include outer surfaces variously defining lower surfaces, sidewalls, etc. of the pad PAD. A lower surface of the first portion PT1 may include a lower surface BPL parallel to the first direction DR1 and the second direction DR2. The lower surface BPL of the pad PAD at the first portion PT1 may be referred to as a bottom surface BPL.

The second portion PT2 may extend from the virtual boundary at the bottom surface BPL, in the third direction DR3. The second portion PT2 may extend from an edge of the first portion PT1 in the third direction DR3. As the second portion PT2 protrudes from the first portion PT1, a dummy groove DGR may be defined by the bottom surface BPL of the first portion PT1 and inner side surfaces of the pad PAD, which face each other, of opposite inner side surfaces of the second portion PT2.

The second portion PT2 may have a rectangular frame shape when viewed on a plane. A lower surface PPL of the second portion PT2 may surround the bottom surface BPL when viewed on a plane. The lower surface PPL of the pad PAD at the second portion PT2 may be referred to as a protrusion surface PPL. The protrusion surface PPL may be the lowermost surface (or point) of the pad PAD, while the upper surface UP may be the uppermost surface (or point) of the pad PAD.

The lower surface PPL of the second portion PT2 may include a curved surface defining a lowermost surface or tip of the pad PAD. The lower surface PPL of the pad PAD at the second portion PT2 may be referred to as the protrusion surface PPL. The protrusion surface PPL may surround the bottom surface BPL when viewed on a plane.

An overall lower surface of the pressing part PSP may have a stepped portion. A height of the bottom surface BPL and a height of the protrusion surface PPL relative to a reference surface, may be different from each other. The height of the bottom surface BPL from such reference surface may be greater than the height of the protrusion surface PPL from such reference surface. The protrusion surface PPL may be more adjacent to (e.g., closer to) the mold MD and the jig JG than the bottom surface BPL is to the mold MD and the jig JG. The bottom surface BPL may be more adjacent to the base surface BS than the protrusion surface PPL is to the base surface BS.

As the height of the protrusion surface PPL is less than the height of the bottom surface BPL, when the pad PAD moves toward the mold MD, the protrusion surface PPL may come into contact with the upper surface UPL of the mold MD, and the bottom surface BPL may not come into contact with the upper surface UPL of the mold MD. Accordingly, the ink INK contained in the ink groove IS of the mold MD may be adhered to only the protrusion surface PPL (e.g., not to the bottom surface BPL). The adhering of the ink INK to the protrusion surface PPL will be described later in detail.

Referring to FIGS. 2 and 3, the protrusion surface PPL at the protrusion of the pad PAD may include a first surface PL1 and a second surface PL2 each extended from a common point (e.g., the tip, the distal end, the lowermost surface, etc.). Specifically, when a virtual plane IPL in contact with the protrusion surface PPL is parallel to a plane defined by the first direction DR1 and the second direction DR2, a contact point of the protrusion surface PPL with the virtual plane IPL may be defined as a reference point SP. An inner surface of the pad PAD which is adjacent to the bottom surface BPL on the basis of the reference point SP may be defined as the first surface PL1. An outer surface of the pad PAD which is adjacent to the base surface BS on the basis of the reference point SP may be defined as the second surface PL2. The second surface PL2 may surround the first surface PL1 when viewed on a plane. The first surface PL1 and the second surface PL2 may be each a convexly curved surface when viewed in the second direction DR2.

An opening provided in plural such as a plurality of opening portions OP may be defined in the pad PAD. The opening portions OP may be defined to pass through the pad PAD. The opening portions OP may extend from the upper surface UP of the body part SPP to the bottom surface BPL in the third direction DR3. Although two opening portions OP are defined as an example, the number of the opening portions OP is not limited thereto.

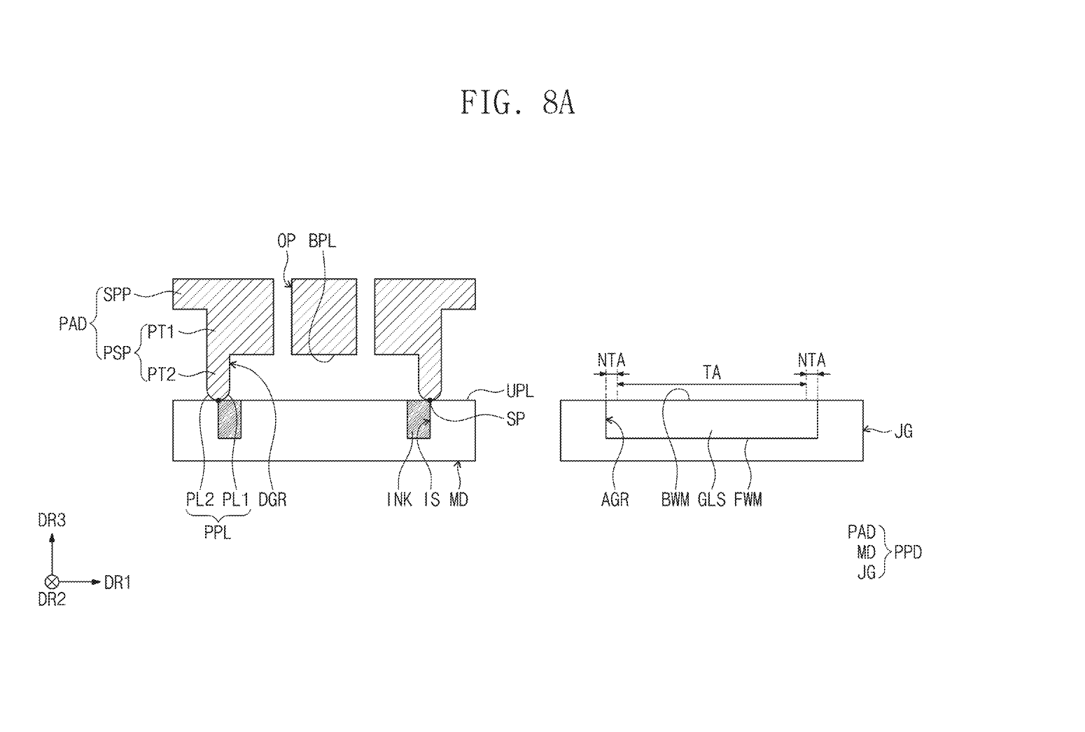

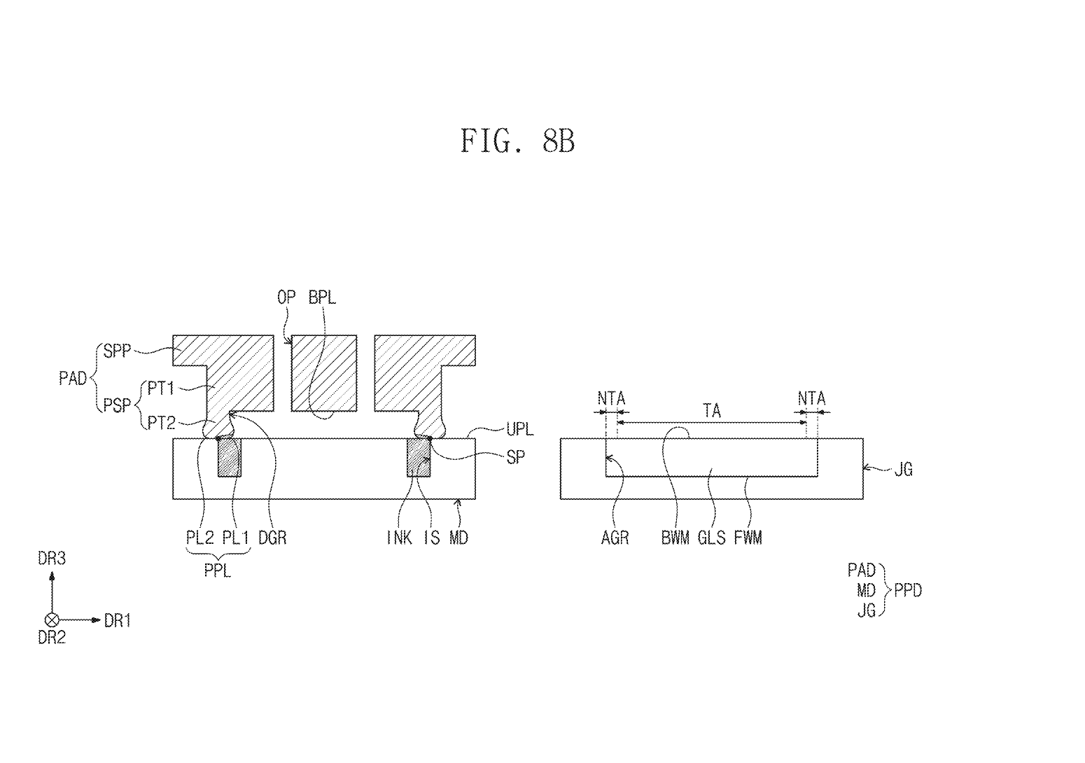

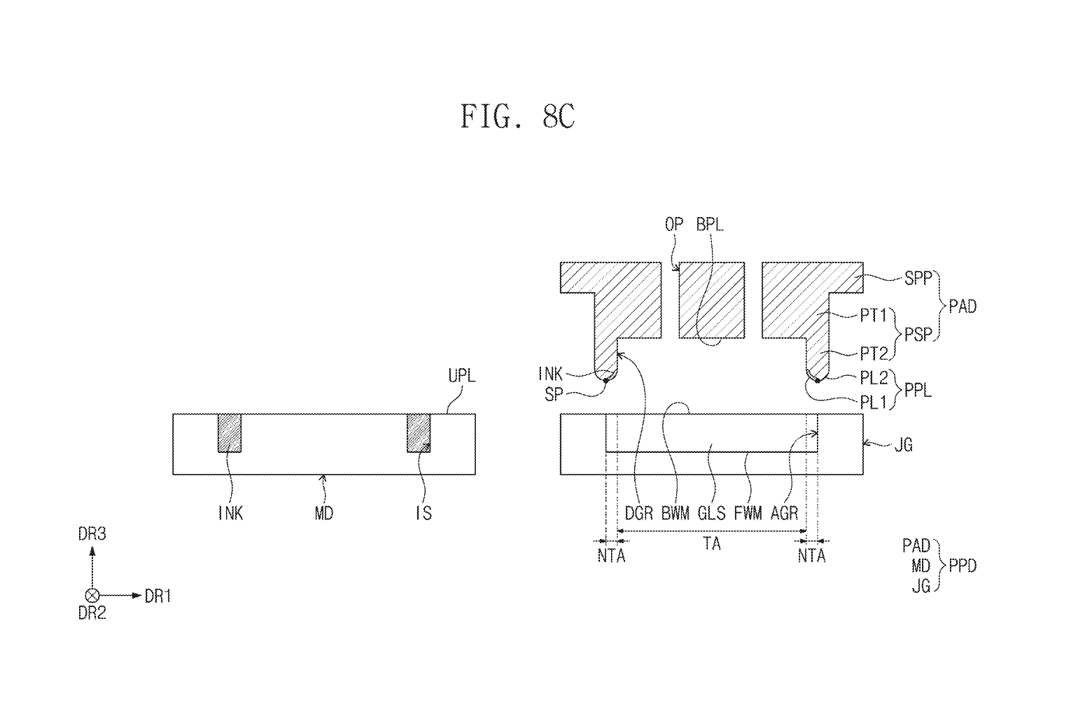

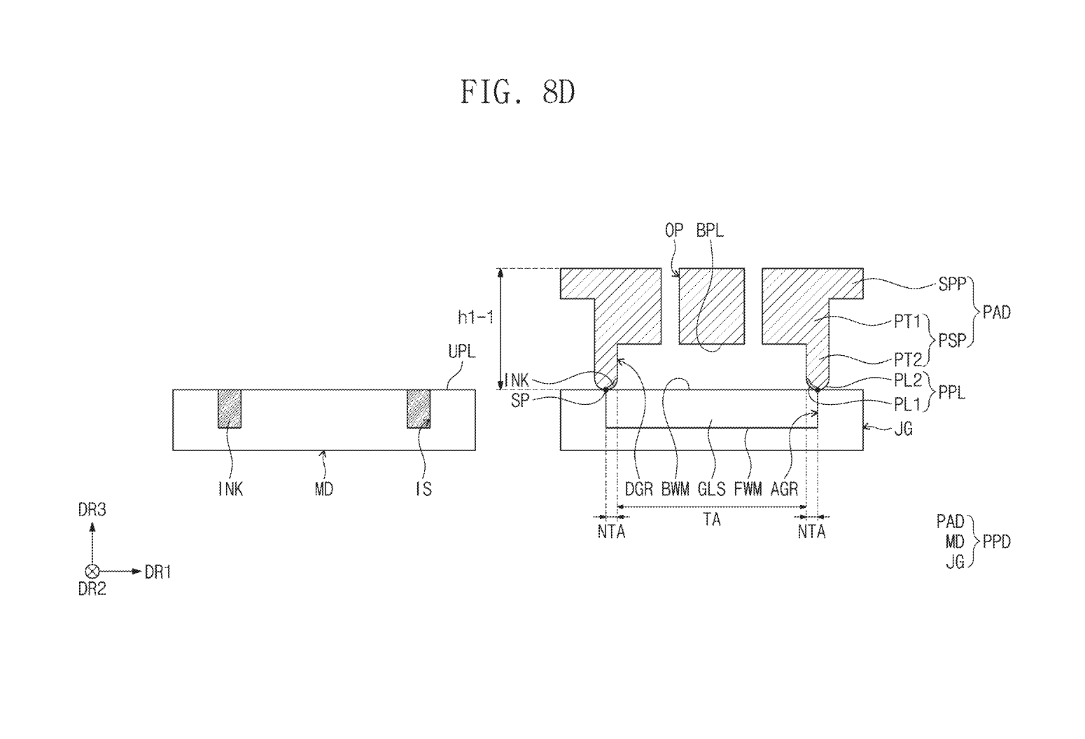

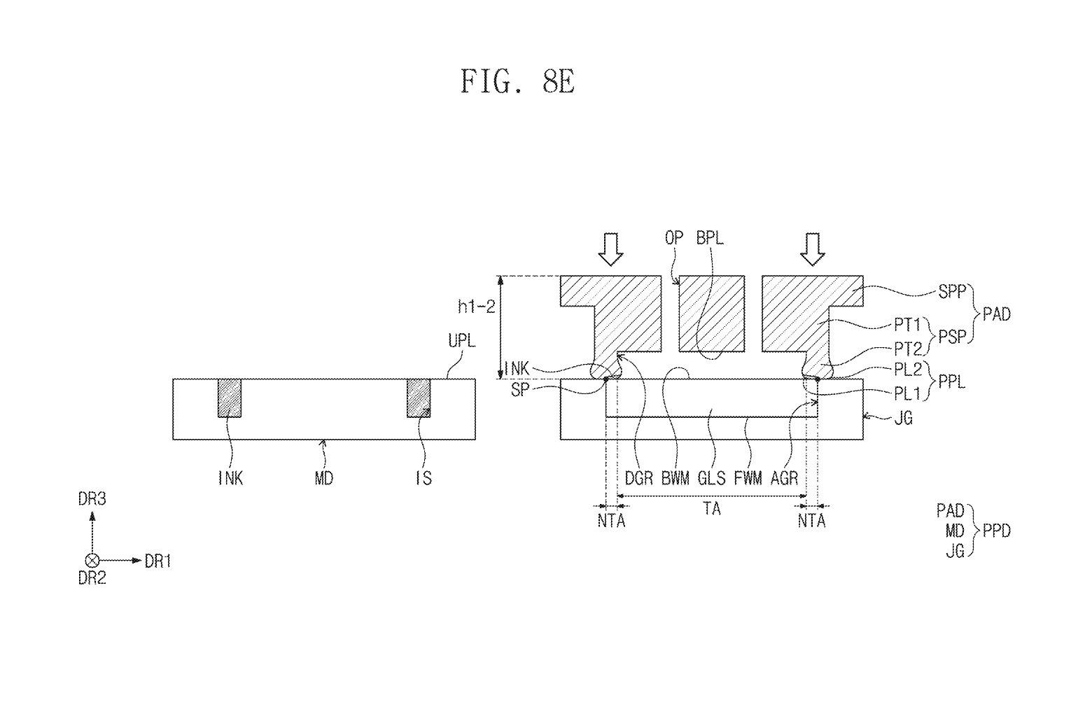

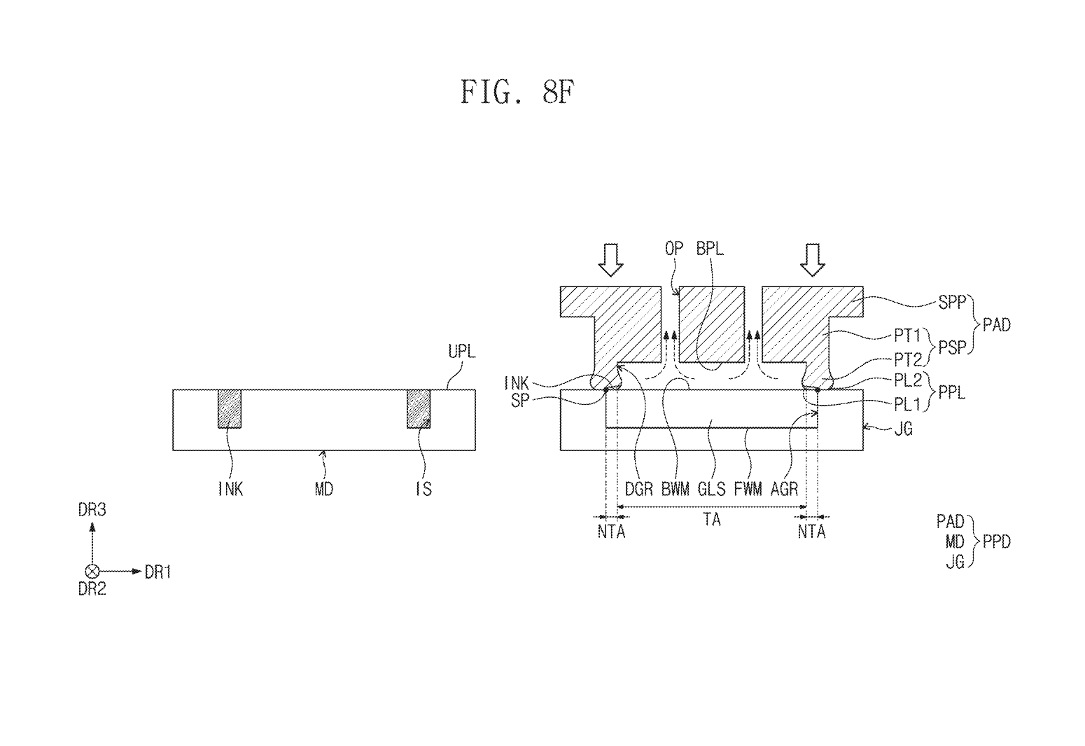

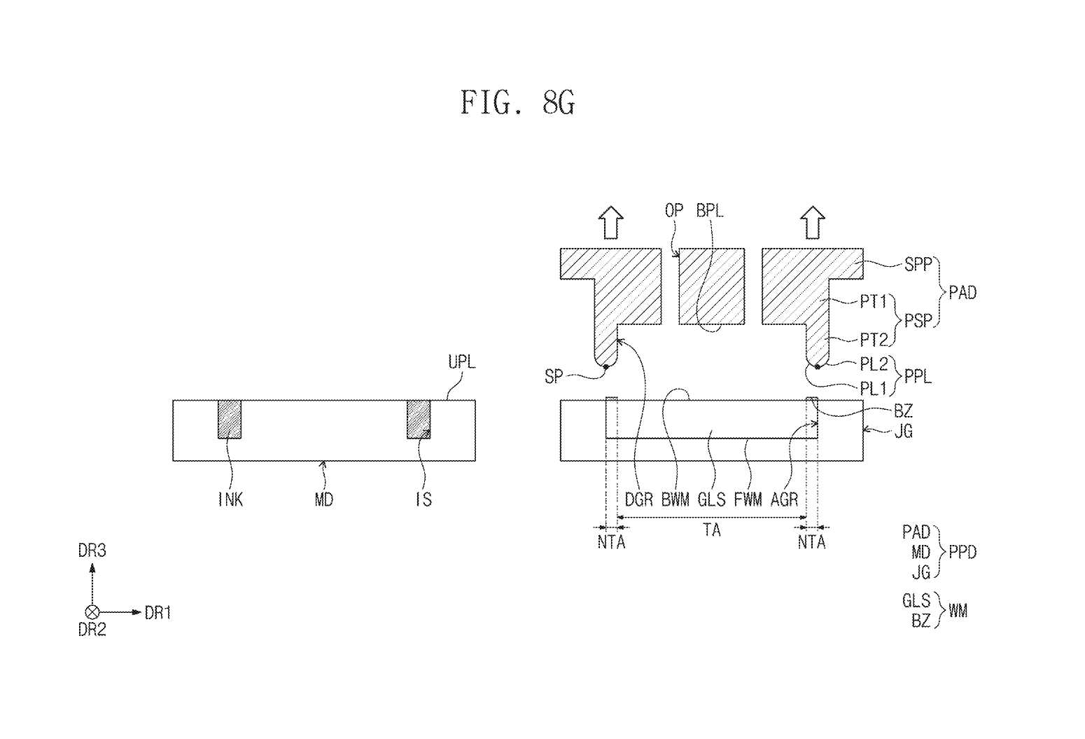

As the opening portions OP are defined in the pad PAD. The opening may penetrate completely through a material (solid) portion of the pad PAD, such as through thickness portions at the body part SPP and the first portion PT1. The opening may be open to outside the pad PAD at both the upper surface UP and a lower surface (e.g., the bottom surface BPL). When the pad PAD is brought into contact with a glass GLS (see FIG. 8D) to be described, air in the dummy groove DGR of the pad PAD may flow from the dummy groove DGR to the outside of the pad PAD through the opening portions OP. The travel of the air through the opening portions OP will be described later in detail.

The jig JG may be disposed adjacent to the mold MD. As an example, the jig JG may be adjacent to the mold MD in a planar direction such as the first direction DR1. The jig JG and the mold MD may be arranged in the first direction DR1.

The jig JG may have a rectangular parallelopiped shape having short sides extending in the first direction DR1 and having long sides extending in the second direction DR2 crossing the first direction DR1. However, the shape of the jig JG is not limited thereto.

An accommodation groove AGR may be defined in an upper surface of the jig JG. The accommodation groove AGR as an opening in the jig JG may extend from the upper surface toward a lower surface of the jig JG in the third direction DR3. The groove may be open to outside the jig JG, at least at the upper surface of the jig body. The groove may or not be open to outside the jig body at the lower surface.

A glass GLS (see FIG. 8A) to be described later may be disposed in the accommodation groove AGR. The accommodation groove AGR may have a shape corresponding to the target substrate as the glass GLS (see FIG. 8A). As an example, the accommodation groove AGR may have a shape corresponding to a portion of a rectangular parallelopiped, but the shape of the accommodation groove AGR is not limited thereto.

Although not illustrated, the pad printing device PPD may further include a driving device. The driving device such as a driver may function or operate to move the pad PAD in the first direction DR1 or the third direction DR3. That is, the driver may be connected (e.g., mechanically, electrically, fluidly, etc.) to the pad PAD to allow the pad PAD to be moveable in various directions relative to the jig JG, the mold MD, the target substrate, etc.

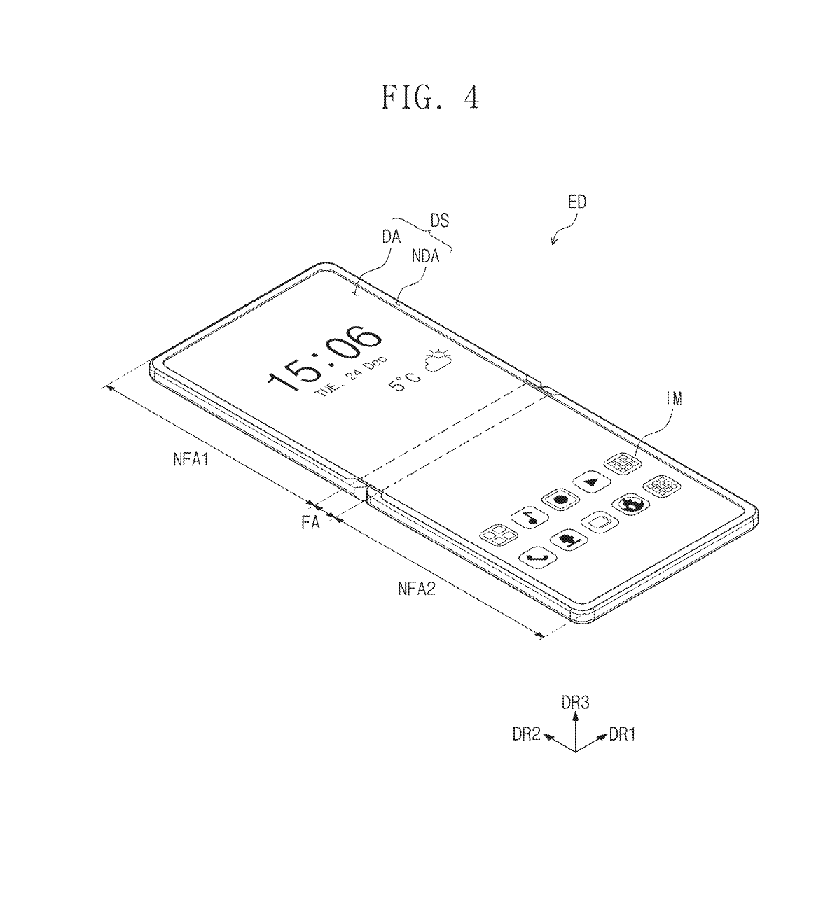

FIG. 4 is a perspective view of an electronic device ED manufactured (or provided) by the pad printing device PPD illustrated in FIG. 1.

Referring to FIG. 4, an electronic device ED according to an embodiment of the invention may have a rectangular shape having short sides extending in the first direction DR1 and having long sides extending in the second direction DR2. However, an embodiment of the invention is not limited thereto, and the electronic device ED may have various planar shapes such as a circular shape and a polygonal shape. The electronic device ED may be flexible.

The electronic device ED may include a folding area FA and a non-folding area provided in plural such as a plurality of non-folding areas NFA1 and NFA2. The non-folding areas NFA1 and NFA2 may include a first non-folding area NFA1 and a second non-folding area NFA2. The folding area FA may be disposed between the first non-folding area NFA1 and the second non-folding area NFA2. The folding area FA, the first non-folding area NFA1, and the second non-folding area NFA2 may be arranged in the first direction DR1.

Although one of the folding area FA and two non-folding areas NFA1 and NFA2 are illustrated as an example, the number of the folding area FA and the number of non-folding areas NFA1 and NFA2 are not limited thereto. For example, the electronic device ED may include a plurality of non-folding areas more than two, and a plurality of folding areas, each of which is disposed between the more than two non-folding areas.

A top surface of the electronic device ED may be defined as a display surface DS, and the display surface DS may be disposed in a plane defined by the first direction DR1 and the second direction DR2. One or more image IM generated in the electronic device ED may be visible from outside the electronic device ED, such as being provided for a user of the electronic device ED, through the display surface DS.

The display surface DS may include a display area DA and a non-display area NDA which is adjacent to the display area DA, such as being extended along or around the display area DA. The display area DA may display an image IM, and the non-display area NDA may not display an image IM. The non-display area NDA may surround the display area DA in the plan view and/or define an edge of the electronic device ED. The non-display area NDA may correspond to a planar area which has a certain aesthetic feature, such as being printed in a certain color.

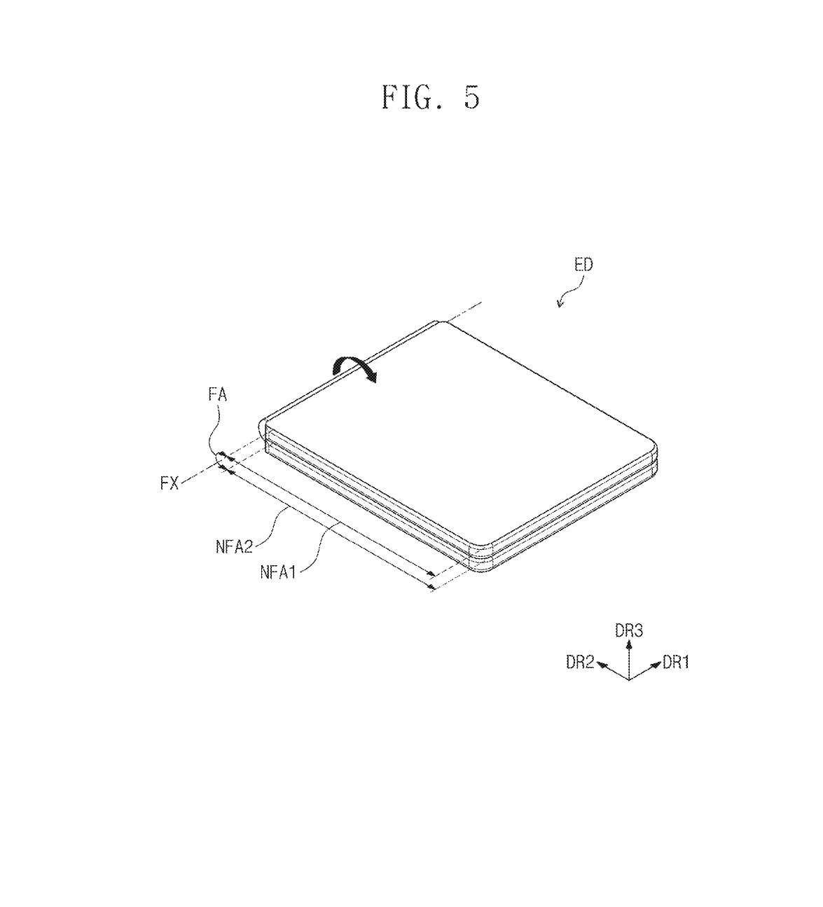

FIG. 5 is a view illustrating a folded state of the electronic device illustrated in FIG. 4.

Referring to FIG. 5, the electronic device ED may be a folding (foldable) electronic device ED which is folded or unfolded. For example, a folding area FA may be bent around (or about) a folding axis FX parallel to the first direction DR1 so that the electronic device ED is folded. The folding axis FX may be defined as an axis parallel to short sides of the electronic device ED. When the electronic device ED is folded, the first non-folding area NFA1 and the second non-folding area NFA2 may face each other along a thickness direction, and the electronic device ED may be in-folded so that the display surface DS is not exposed to the outside. However, an embodiment of the invention is not limited thereto. For example, although not illustrated, the electronic device ED may be out-folded around the folding axis FX so that portions of the display surface DS face in opposite directions from each other to be exposed to the outside (e.g., outside of the electronic device ED). Alternatively, although not illustrated, the electronic device ED may allow for simultaneous in-folding and out-folding of device portions.

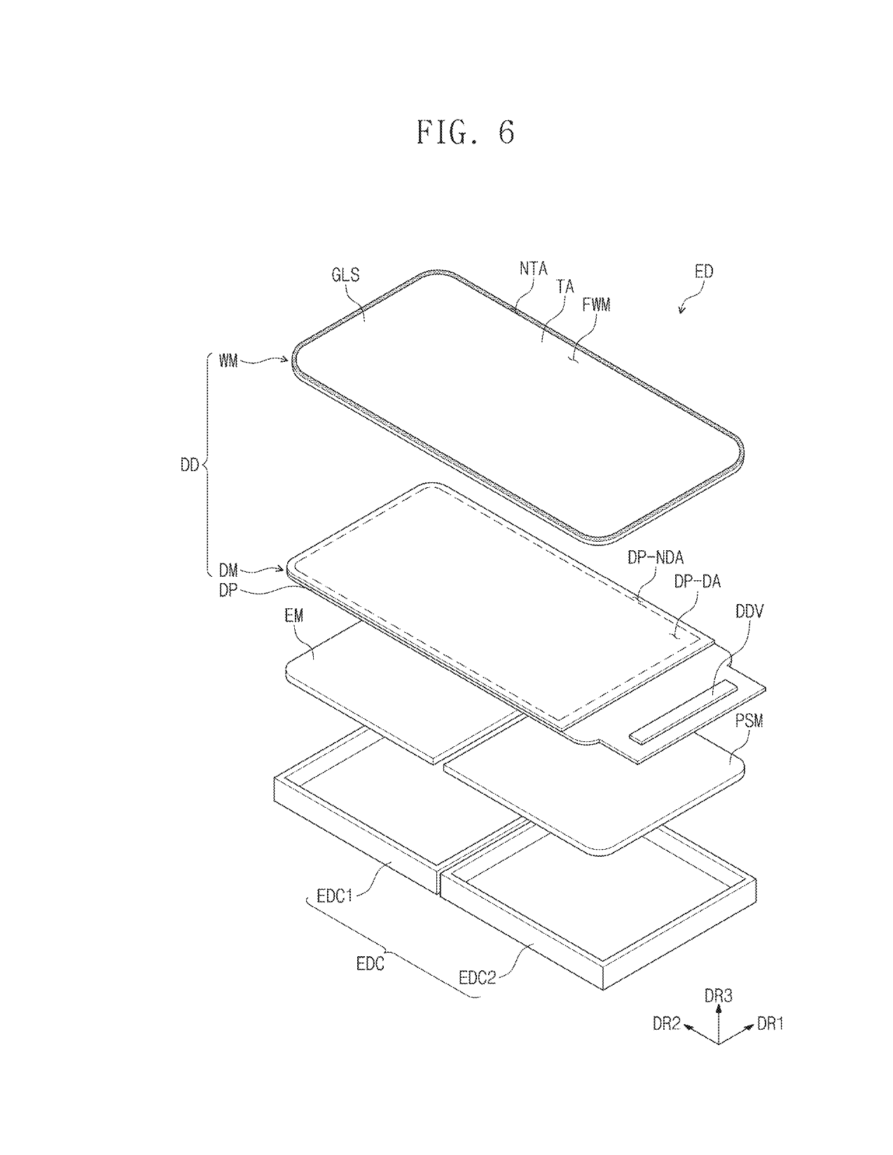

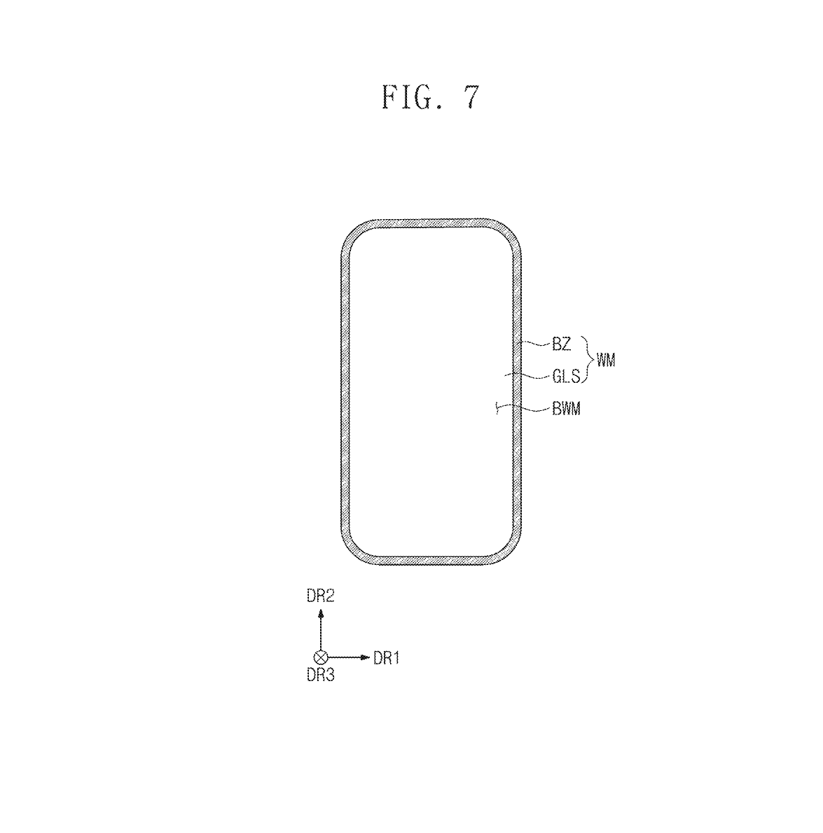

FIG. 6 is an exploded perspective view of the electronic device ED illustrated in FIG. 4. FIG. 7 is a plan view of a rear surface of a window WM illustrated in FIG. 6.

Referring to FIGS. 6 and 7, the electronic device ED may include a display device DD, an electronic module EM, a power module PSM, and a case EDC. Although not illustrated, the electronic device ED may further include a mechanical structure (e.g., a hinge) for controlling a folding operation of the display device DD. The display device DD may be foldable together with other components of the electronic device ED, such as the electronic module EM, the case ECC, etc.

The display device DD may generate an image IM and/or sense an external input. The display device DD may include a window WM and a display module DM which faces the window WM. The window WM may provide a front surface of the electronic device ED. The front surface of the electronic device ED may be exposed to outside the electronic device ED. The window WM may be disposed on the display module DM and transmit an image IM provided from the display module DM, to the outside. The window WM may transmit light generated from the display module DM and provide the light to the outside, such as for the user.

The window WM may include a transmission area TA and a non-transmission area NTA. The transmission area TA may overlap the display area DA illustrated in FIG. 4, and have a planar shape corresponding to the display area DA.

The non-transmission area NTA may overlap the non-display area NDA illustrated in FIG. 4, and have a planar shape corresponding to the non-display area NDA. The non-transmission area NTA may be an area (e.g., a planar area) having a relatively lower light transmittance than a light transmittance of the transmission area TA. However, an embodiment of the invention is not limited thereto, and the non-transmission area NTA may be omitted.

The window WM may include a glass GLS and a bezel pattern BZ. The glass GLS may include glass, sapphire, plastic, or the like. The glass GLS may include an optically transparent insulating material. For example, the glass GLS may include a glass or plastic film, or include a glass substrate and a plastic film coupled to each other through an adhesive to provide the layer of the glass GLS.

The glass GLS may include a front surface FWM and a rear surface BWM which is opposing the front surface FWM in the third direction DR3. The front surface FWM may be defined as a surface of the glass GLS, which is exposed to the outside. The rear surface BWM may be defined as a surface of the glass GLS, which faces the display module DM.

The bezel pattern BZ may be disposed on the rear surface BWM of the glass GLS. The bezel pattern BZ may overlap an edge of the glass GLS, such as being inwardly extended from an outer edge of the glass GLS. A portion of the glass GLS may be exposed outside of the bezel pattern BZ. A portion of the glass GLS, on which the bezel pattern BZ is not disposed, may correspond to the transmission area TA. A portion of the glass GLS, which overlaps the bezel pattern BZ, may correspond to the non-transmission area NTA. A shape of the bezel pattern BZ will be described in detail with reference to FIGS. 8A to 8G.

Although not illustrated, the window WM may include functional layers (not shown) disposed on the glass GLS. The functional layers may include a protective layer, an anti-fingerprint layer, an anti-reflective layer and the like. One or more of the functional layers may provide the outer surface of the window WM. That is, a functional layer may be on the top surface and/or a bottom surface of the body of the glass GLS (e.g., a glass body of the window WM).

The display module DM may include a display panel DP. FIG. 6 illustrates only the display panel DP of a stack structure of the display module DM, but the display module DM may substantially further include a plurality of components or layers (not shown) disposed on an upper side and a lower side of the display panel DP. The display panel DP may include a display area DP-DA and a non-display area DP-NDA respectively corresponding to the display area DA and the non-display area NDA in FIG. 4 of the electronic device ED

The display module DM may include a data driver DDV disposed on the non-display area DP-NDA of the display panel DP. The data driver DDV may be manufactured (or provided) in the form of an integrated circuit chip and mounted on the display panel DP, at the non-display area NDA. However, an embodiment of the invention is not limited thereto, and the data driver DDV may be mounted on a flexible circuit board which is a separate component from and connected to the display panel DP.

Although not illustrated, an anti-reflective layer as a function layer, may be disposed between the window WM and the display module DM. The anti-reflective layer may reduce reflectance of external light incident from the outside of the display device DD. The anti-reflective layer may include color filters. The color filters may have a certain arrangement. For example, the color filters may be arranged in light of emissive colors of pixels included in the display panel DP to be described later. In addition, the anti-reflective layer may further include a black matrix adjacent to the color filters.

The electronic module EM and the power module PSM may be disposed below the display device DD. Although not illustrated, the electronic module EM and the power module PSM may be connected to each other (e.g., electrically connected) through a separate member such as a flexible circuit board. The electronic module EM may control an operation of the display device DD. The power module PSM may supply power to the electronic module EM.

The case EDC may accommodate the display device DD, the electronic module EM, and the power module PSM. The case EDC may include two sub-cases, first and second cases EDC1 and EDC2, in order that the display device DD may be foldable. The first and second cases EDC1 and EDC2 may extend in the first direction DR1 and be arranged adjacent to each other in the second direction DR2.

Although not illustrated, the electronic device ED may further include a hinge structure for hingedly connecting the first and second cases EDC1 and EDC2 to each other. The case EDC may be coupled to the window WM. The case EDC may protect the display device DD, the electronic module EM, and the power module PSM. The case EDC and the window WM may together form an outer surface of the electronic device ED which has an aesthetic design.

FIGS. 8A to 8G are cross-sectional views for describing a method for manufacturing (or providing) the window WM illustrated in FIG. 6.

FIGS. 8A to 8G illustrate cross-sectional views of a pad printing device PPD and a glass GLS when viewed in the second direction DR2. It will be understood that the same or similar principles of the method may be applied in views along the first direction DR1.

A plurality of reference points SP, a plurality of first surfaces PL1, and a plurality of second surfaces PL2 are illustrated as an example in FIGS. 8A to 8G. However, as substantially as illustrated in FIG. 2, the reference points SP may be extended to be provided as a single closed curve of a protrusion surface PPL, the first surfaces PL1 may be provided as one body, and the second surfaces PL2 may be provided as one body. That is, a protruded portion of the pad PAD may include the second portion PT2 defining the protrusion surfaces and the reference point SP.

A plurality of non-transmission areas NTA are illustrated as an example in FIGS. 8A to 8G, but the non-transmission areas NTA may be provided substantially as one area extended along the glass body.

Among components illustrated in FIGS. 8A to 8G, components the same as/similar to the components described with reference to the foregoing drawings will not be described or will be described in brief.

Referring to FIG. 8A, a method for manufacturing the window WM (see FIG. 7) may include disposing the glass GLS as a target substrate, which includes a transmission area TA and the non-transmission areas NTA, in an accommodation groove AGR defined open at an upper surface of a jig JG. A rear surface BWM of the glass GLS may be disposed so as to be exposed from the jig JG at the accommodation groove AGR, to the outside of the jig JG. The rear surface BWM of the glass GLS may be disposed at a higher position than a front surface FWM of the glass GLS, along a thickness direction of the jig JG.

Referring to FIGS. 8A and 8B, the location of an ink groove IS corresponds to a location of the protruded portion of the pad PAD. Moving a pad PAD including a pressing part PSP downward to contact and/or adhere an ink INK exposed at an upper surface UPL of a mold MD, to a lower surface of the pressing part PSP, may be performed after the glass GLS is disposed in the accommodation groove AGR. In an embodiment, the moving of the pad PAD and the providing the target substrate in the jig JG may be done simultaneously, without being limited thereto. As being in contact, elements may form an interface therebetween.

The pad PAD may be moved in the third direction DR3 to come into contact with the upper surface UPL of the mold MD. The protrusion surface PPL of the pad PAD may come into contact with the upper surface UPL of the mold MD. A bottom surface BPL of the pad PAD may not come into contact with the upper surface UPL of the mold MD. That is, the pad PAD may come into contact with the ink INK at the reference point SP and surfaces of the protrusion which are extended from (or adjacent to the reference point SP).

When viewed in the second direction DR2, the reference points SP may overlap a boundary between the upper surface UPL of the mold MD and the ink INK which is disposed in an ink groove IS. The reference points SP may be disposed at the boundary between the upper surface UPL of the mold MD and the ink INK, and then the pad PAD may be further moved in the third direction DR3. The pad PAD having elasticity may be deformed at the distal end thereof so that the ink INK is adhered to the protrusion surface PPL adjacent to the reference point SP.

When the pad PAD is deformed to increase a contact area of the protruded portion of the pad PAD with the mold MD, the first surfaces PL1 may come into contact with the ink INK. The second surfaces PL2 may come into contact with the upper surface UPL of the mold MD which is adjacent to the ink INK. The second surfaces PL2 may not come into contact with the ink INK. Accordingly, the ink INK may be adhered to the first surfaces PL1 at an inner side of the protruded portion of the pad PAD. The ink INK may not be adhered to the second surfaces PL2 at an outer side of the protruded portion of the pad PAD.

Referring to FIGS. 8B and 8C, movement of the PAD includes removing the pad PAD from the mold MD, and positioning the pad PAD to be above the jig JG to dispose the pad PAD above the glass GLS. The movement and re-positioning of the pad PAD may be performed after the ink INK is adhered to the protrusion surface PPL. That is, the pad PAD having the ink INK adhered thereto, is transferred between the mold MD and the jig JG having the target substrate therein. The pad PAD may be moved in the third direction DR3 to be spaced apart from the mold MD. The pad PAD may be moved in the first direction DR1 to be disposed above the jig JG. The pad PAD may be disposed above the glass GLS. Here, the pad PAD and the jig JG having the target substrate may not be in contact with each other.

Referring to FIG. 8D, the location of the non-transmission areas NTA correspond to the location of the protruded portion of the pad PAD Only an inner portion of the protrusion relative to the reference point SP overlaps the glass GLS, while an outer portion of the protrusion relative to the reference point SP is non-overlapping the glass GLS. For example, the outer portion may overlap an end portion of the jig JG which is adjacent to the outer edge of the glass GLS.

Referring to FIG. 8D, moving the pad PAD down toward the glass GLS to press the glass GLS may be performed. The pad PAD may be moved in the third direction DR3 to come into initial contact with respective upper surfaces of the glass GLS and the jig JG. The protrusion surface PPL may come into contact with the glass GLS, such as at the non-transmission areas NTA. A bottom surface BPL of the PAD may be spaced apart from the glass GLS and the jig JG.

As the bottom surface BPL is spaced apart from the glass GLS, a total contact surface area between the pad PAD and the glass GLS may be decreased. Accordingly, foreign matter attached to the bottom surface BPL may be prevented from being transferred to a surface of the glass GLS. Thus, when an adhesive for bonding the glass GLS to the display module DM (see FIG. 6) is disposed on the glass GLS in a method for providing the electronic device ED, adhesion between the glass GLS and the adhesive may be prevented from being decreased, and a defect in the display device DD (see FIG. 6) may be prevented.

The reference points SP of the protrusion surface PPL may initially come into contact with an outer edge of the glass GLS. The outer edge of the glass GLS may form a boundary with an inner sidewall (e.g., inner edge) of the jig JG which defines the accommodation groove AGR. That is, the reference points SP of the protrusion surface PPL may initially come into contact with the combined structure of the glass GLS and the jig JG, at the boundary. Here, the non-transmission areas NTA may have opposing sides along the first direction DR1, one (outer) side corresponding to the boundary, and one (inner) side (dotted line in FIG. 8D) spaced apart from the outer side.

Each of the reference points SP may be contacted from above with the one outer side spaced apart from the transmission area TA, of the two opposite sides of each of the non-transmission areas NTA in the first direction DR1. The first surfaces PL1 at the inner side of the reference point SP may overlap the non-transmission areas NTA of the glass GLS. The second surfaces PL2 at the outer side of the reference point SP may not overlap the glass GLS, but may instead overlap the end portion of the jig JG which extends outwardly from the outer edge of the glass GLS.

Referring to FIGS. 8D and 8E, the pad PAD may be further moved in the third direction DR3 after the pad PAD is in initially contact with the glass GLS, to increase a contact area between the pad PAD and the underlying combined structure. The pad PAD having elasticity may be deformed at the distal end of the protruded portion. A thickness of the pad PAD may be changed from a (1-1)-th length h1-1 to a (1-2)-th length h1-2. The (1-1)-th length h1-1 may be defined as a thickness of the pad PAD before deformation. The (1-2)-th length h1-2 may be defined as a thickness of the pad PAD after deformation.

As the pad PAD is deformed, the first surfaces PL1 having the ink INK adhered thereto may come into contact with the non-transmission areas NTA. The ink INK adhered to the first surfaces PL1 may be transferred to and adhered to the non-transmission areas NTA by the increased contact area between the pad PAD and the underlying combined structure. The second surfaces PL2 may not come into contact with the glass GLS. The second surfaces PL2 may instead come into contact with the upper surface of the body of the jig JG which is adjacent to the outer edge of the glass GLS.

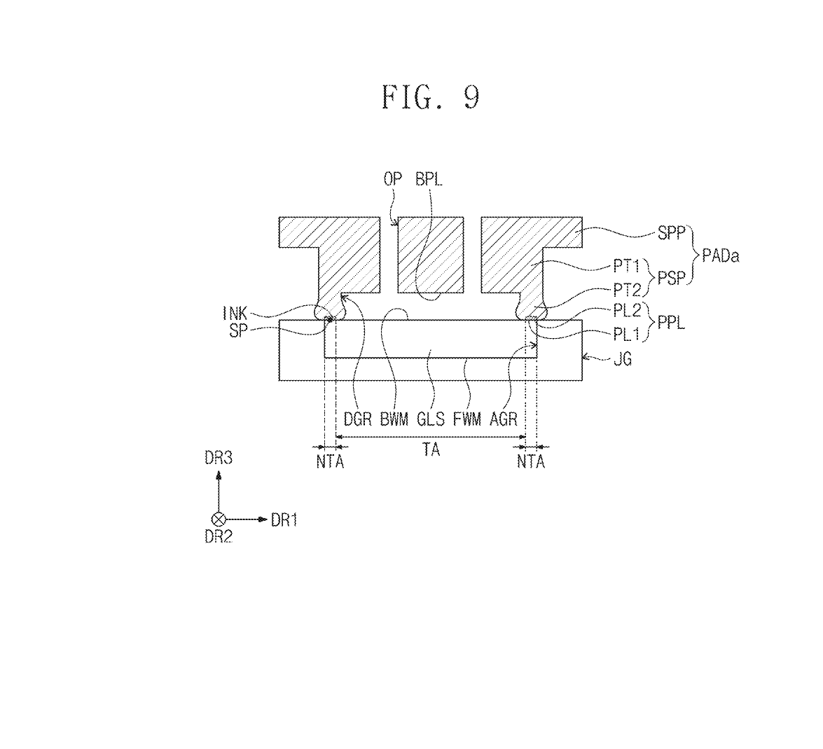

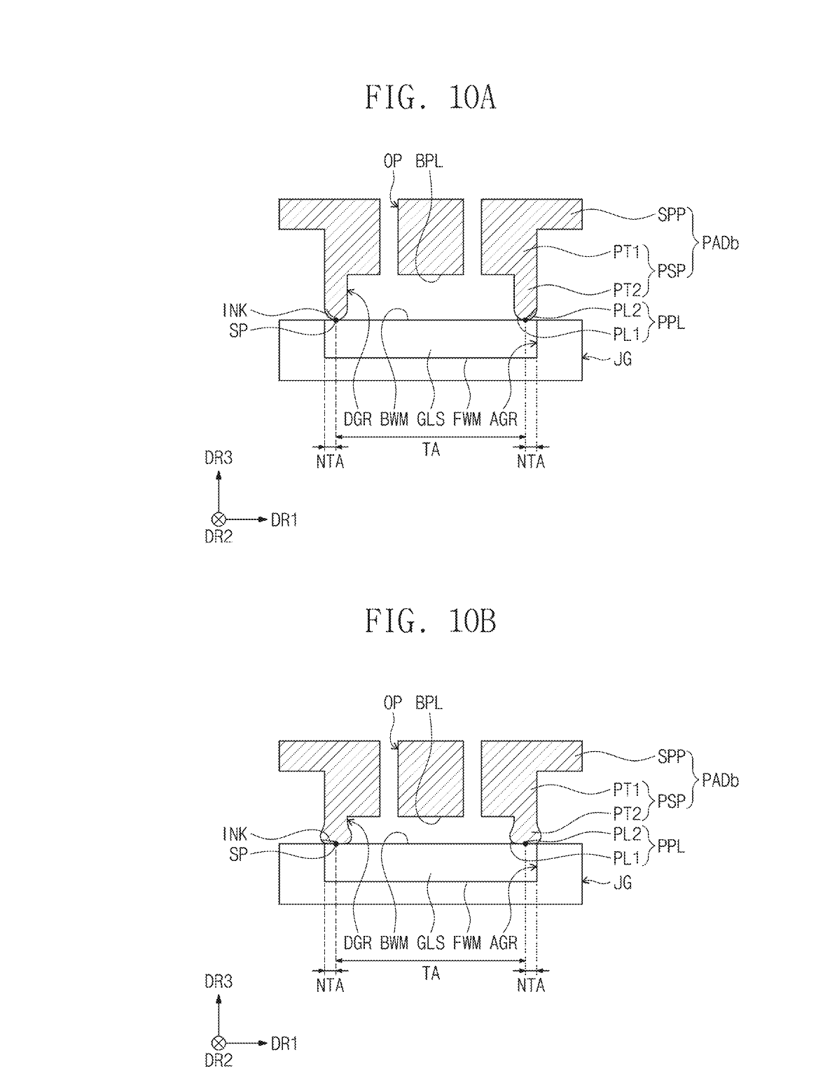

FIG. 9 is a view illustrating a pad PADa according to a comparative example. FIGS. 10A and 10B are views illustrating a pad PADb according to a comparative example.

FIGS. 9 to 10B illustrate cross-sectional views of pads PADa and PADb, and a jig JG, when viewed in the second direction DR2.

A plurality of reference points SP, a plurality of first surfaces PL1, and a plurality of second surfaces PL2 are illustrated as an example in FIGS. 9 to 10B, but substantially, the reference points SP may be provided as a single closed curve on a protrusion surface PPL, the first surfaces PL1 may be provided as one body, and the second surfaces PL2 may be provided as one body, within a protruded portion of the pads.

A plurality of non-transmission areas NTA are illustrated as an example in FIGS. 9 to 10B, but the non-transmission areas NTA may be provided substantially as one body.

Referring to FIG. 9, the reference points SP may overlap the non-transmission areas NTA. The ink INK which is positioned centered at the reference points SP may overlap the non-transmission areas NTA. The reference points SP may come into contact with respective centers of the non-transmission areas NTA. The first surfaces PL1 and the second surfaces PL2 which extend in opposing directions from the reference point SP may come into contact with the non-transmission areas NTA.

As all the first surfaces PL1 and the second surfaces PL2 come into contact with the glass GLS, even at a point contact, a contact surface area between the protrusion surface PPL and the glass GLS may be increased. Accordingly, when the pad PADa is moved in a direction away from the glass GLS to be spaced apart from the glass GLS, an ink INK may be moved together with with the pad PADa by viscosity in the third direction DR3. Thus, the ink INK once adhered to the glass GLS may be removed from a rear surface BWM of the glass GLS, and thus printing quality may be decreased.

Referring to FIGS. 10A and 10B, each of the reference points SP may come into contact with the other (inner) side, adjacent to a transmission area TA, of two opposite sides of each of the non-transmission areas NTA in the first direction DR1. When the pad PADb is moved in the third direction DR3 to deform the protruded portion, the first surfaces PL1 at an inner side of the protruded portion may come into contact with the glass GLS at the transmission area TA, and the second surfaces PL2 may come into contact with the glass GLS at the non-transmission areas NTA. As the first surfaces PL1 come into contact with the transmission area TA, foreign matter attached to the protrusion surface PPL may be transferred to the transmission area TA. Accordingly, when an adhesive for bonding the glass GLS to the display module DM (see FIG. 6) is disposed on the glass GLS in a method for providing the electronic device ED, adhesion between the glass GLS and the adhesive may be decreased.

Referring to FIG. 8E, when the pad PAD according to an embodiment of the invention comes into contact with the glass GLS, only an area of the first surfaces PL1 which has the INK may come into contact with the non-transmission areas NTA, and the second surfaces PL2 may not come into contact with the glass GLS, thereby decreasing an overall contact surface area between the protrusion surface PPL and the glass GLS. That is, only the ink INK which is on the pad PAD at the first surface PL1 contacts the glass GLS, such that no portion of the first surface PL1 which is adjacent to the ink INK (e.g., excludes the ink INK) comes into contact with the glass GLS. Accordingly, when the pad PAD is transferred I a direction away from the glass GLS to be spaced apart from the glass GLS, removal of the ink INK from the rear surface BWM of the glass GLS may be reduced or effectively prevented. Thus, the printing quality of the glass GLS may be improved.

In addition, the protrusion surface PPL may not come into contact with the transmission area TA to prevent foreign matter attached to the protrusion surface PPL from being transferred to the transmission area TA. Thus, when an adhesive for bonding the glass GLS to the display module DM (see FIG. 6) is disposed on the glass GLS in a method for providing the electronic device ED, the adhesion between the glass GLS and the adhesive may be prevented from being decreased, and a defect in the display device DD (see FIG. 6) may be prevented.

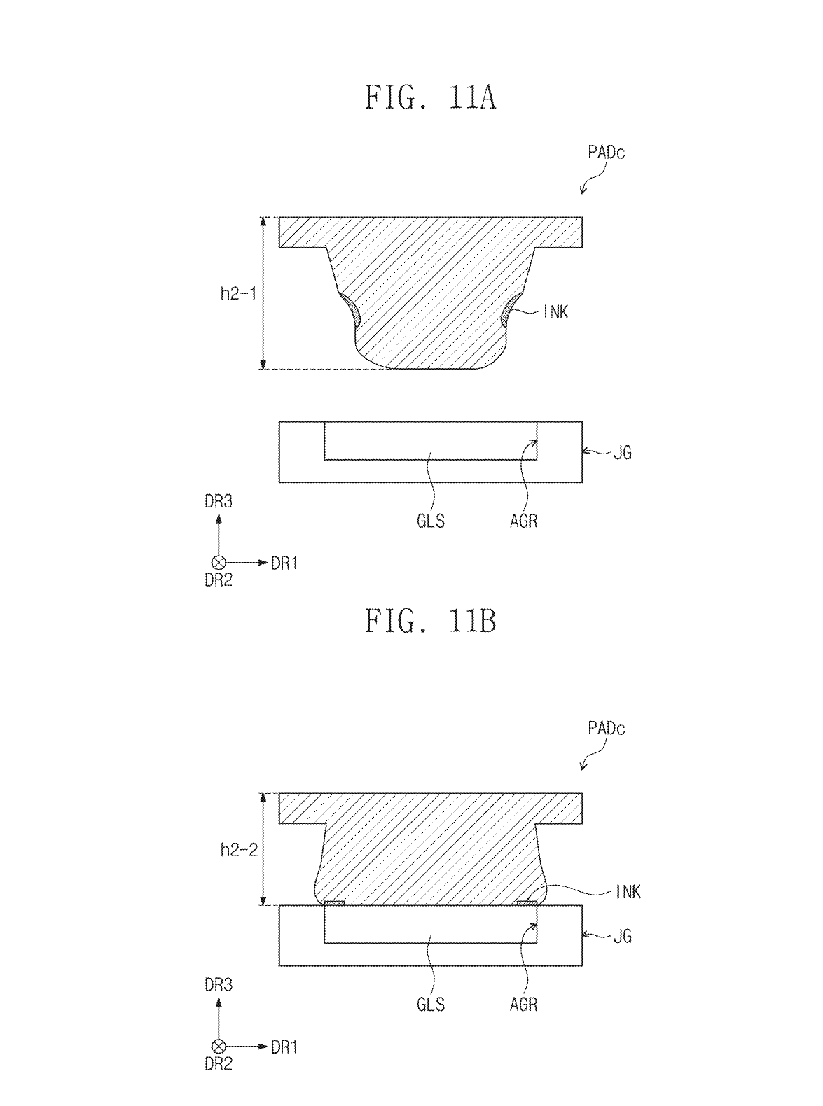

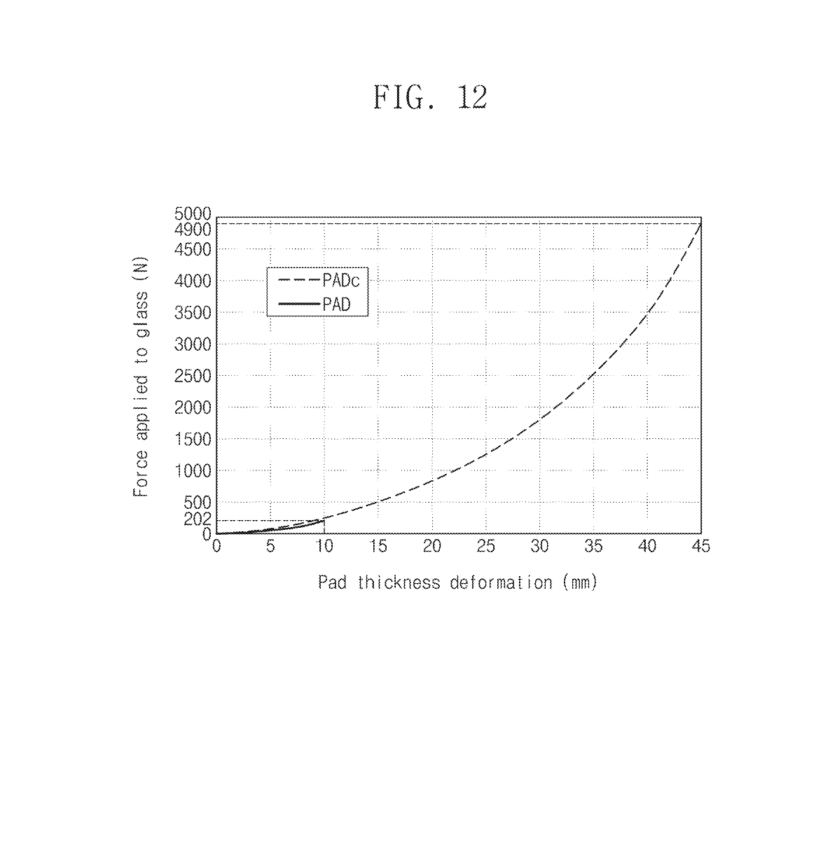

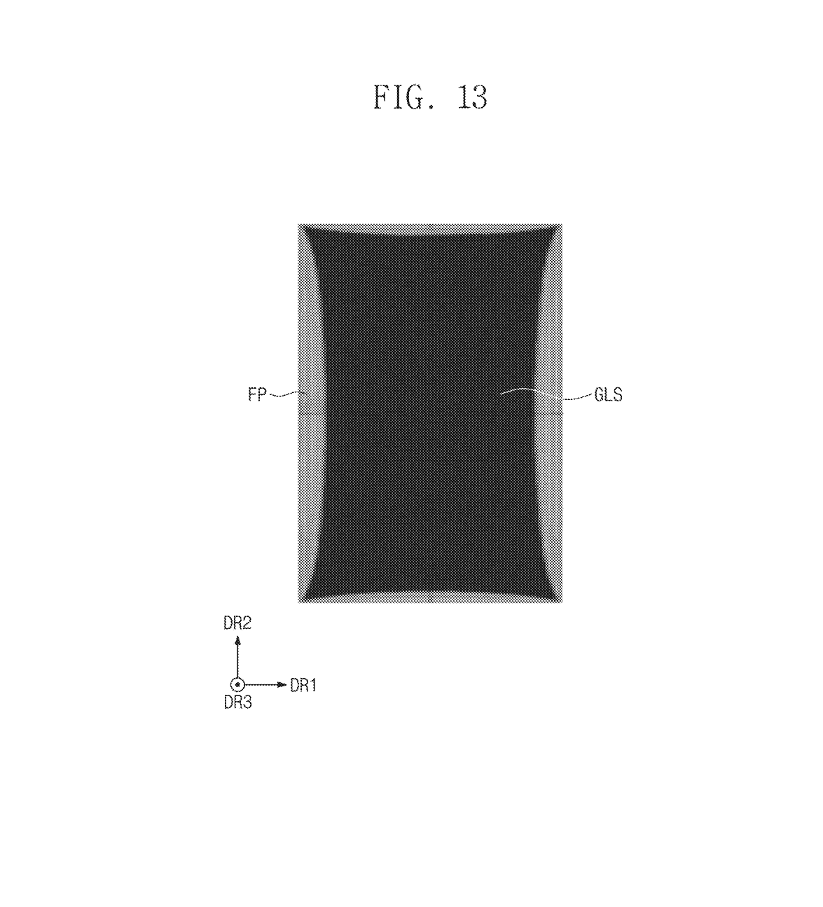

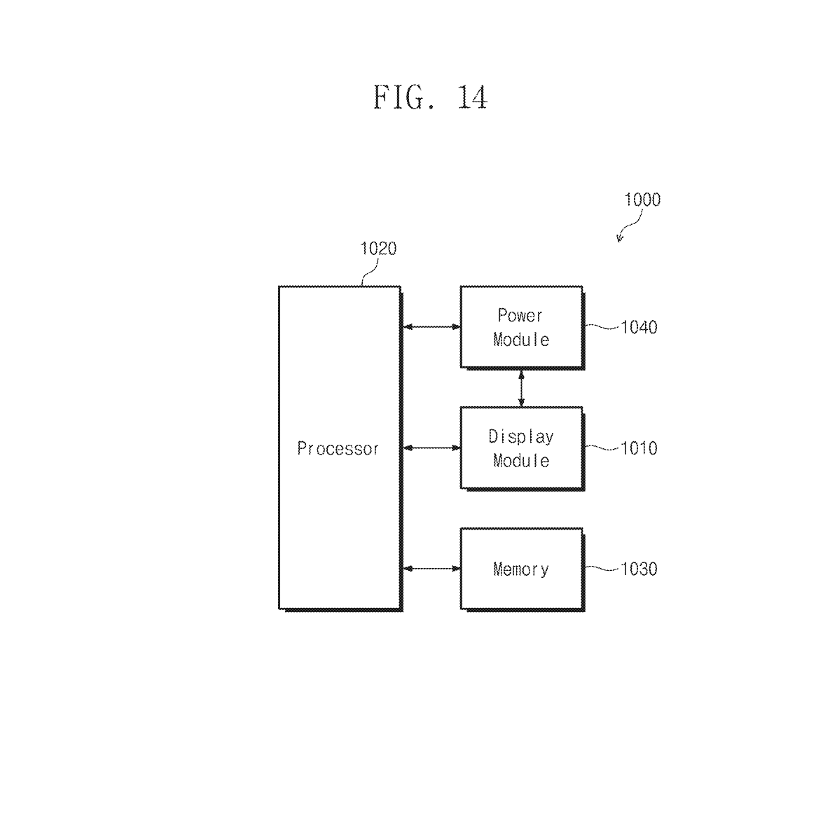

FIGS. 11A and 11B are views illustrating a pad PADc according to a comparative example. FIG. 12 is a graph for describing an amount of thickness deformation (millimeters, mm) for a pad PAD according to an embodiment of the invention and a pad PADc according to a comparative example. FIG. 13 is a plan view of a glass GLS for which a force (newtons, N) is applied to the glass GLS when the glass GLS is pressed using a pad PAD according to an embodiment of the invention.

FIGS. 11A and 11B illustrate cross-sectional views of a pad PADc and a glass GLS when viewed in the second direction DR2.

Among components illustrated in FIGS. 11A to 13, components the same as/similar to the components described with reference to the foregoing drawings will not be described or will be described in brief.

Referring to FIGS. 11A and 11B, an ink INK may be adhered to two opposite sides of the pad PADc according to the comparative example, in the first direction DR1. The pad PADc may be moved toward the glass GLS in the third direction DR3 to come into contact with the glass GLS.

After the pad PADc is in contact with the glass GLS, the pad PADc may be further moved in the third direction DR3 to be deformed (FIG. 11B). The pad PADc may be changed in length from a total (2-1)-th length h2-1 to a total (compressed) (2-2)-th length h2-2. The (2-1)-th length h2-1 may be an uncompressed thickness of the pad PADc before deformation, and the (2-2)-th length h2-2 may be a compressed thickness of the pad PADc after deformation. As the pad PADc is deformed, the ink INK adhered to a respective side surface of the pad PADc may be adhered to the glass GLS.

Referring to FIGS. 8E, 11B, and 12, when the pads PAD and PADc are deformed, the pads PAD and PADc may each press the glass GLS at various planar areas along the glass GLS. A size of a force applied to the glass GLS may be in proportion to an amount of thickness deformation for each of the pads PAD and PADc.

Specifically, in graphs in FIG. 12, an X axis may be defined as the amount of thickness deformation for the pads PAD and PADc in millimeters (mm), and a Y axis may be defined as the size of the force applied to the glass GLS in newtons (N). The graph for the pad PAD according to an embodiment of the invention is indicated by a solid line, and the graph for the pad PADc according to the comparative example is indicated by a dotted line.

The amount of thickness deformation for the pad PAD according to an embodiment of the invention may be defined as a change in length from the (1-1)-th length h1-1 (FIG. 8D) to the (1-2)-th length h1-2 (FIG. 8E). The amount of thickness deformation for the pad PADc according to the comparative example may be defined as a change in length from a (2-1)-th length h2-1 (FIG. 11A) to a (2-2)-th length h2-2 (FIG. 11B).

The amount of thickness deformation for the pad PADc according to the comparative example may be about 45 mm in order that the ink INK, adhered to the two opposite sides of the pad PADc according to the comparative example in the first direction DR1, is adhered to the glass GLS. When the amount of thickness deformation for the pad PADc according to the comparative example is about 45 mm, the size of the force applied to the glass GLS by the pad PADc according to the comparative example may be about 4900 N.

The amount of thickness deformation for the pad PAD according to an embodiment of the invention may be about 10 mm in order that the ink INK adhered to the first surfaces PL1 of the pad PAD is adhered to the glass GLS. When the amount of thickness deformation for the pad PAD according to an embodiment of the invention is about 10 mm, the size of the force applied to the glass GLS by the pad PAD may be about 202 N.

The ink INK may be adhered to a protrusion surface PPL of the pad PAD which is closest to the target substrate according to an embodiment of the invention. Accordingly, even when the amount of thickness deformation for the pad PAD is small, the ink INK may be adhered to a rear surface BWM of the glass GLS. Accordingly, the size of the force applied to the glass GLS by the pad PAD may be decreased. Thus, a damage to the glass GLS may be reduced or effectively prevented.

In contrast, the ink INK adhered to the pad PADc at a distance from a distal end of the protrusion (FIG. 11A) is transferred to the target substrate by a relatively large force. Accordingly, the size of the force applied to the glass GLS by the pad PADc may be relatively large such that the glass GLS may be damaged.

Referring to FIGS. 2, 8E, and 13, the force applied by the pad PAD is visualized as patterns FP disposed on an edge of a glass GLS in FIG. 13. As illustrated in FIG. 2, the protrusion surface PPL may have a rectangular frame shape when viewed on a plane, thereby applying uniform pressure at the outer edge of the glass GLS. Accordingly, the ink INK may be uniformly adhered along the long sides and short sides of the glass GLS. Thus, the quality of window WM (see FIG. 7) may be improved.

Referring to FIGS. 8F and 8G, removing the pad PAD from the glass GLS to form a bezel pattern BZ on the edge of the glass GLS may be performed after the ink INK is adhered to the rear surface BWM of the glass GLS. The pad PAD may be moved in the third direction DR3 and moved in a direction which is away from the glass GLS.

When the pad PAD presses the glass GLS (downward arrows in FIG. 8F), air inside a dummy groove DGR may be compressed or pressed against the underlying combined structure. In a case in which opening portions OP are not defined in the pad PAD, the glass GLS may be physically moved along with (e.g., together with) the pad PAD by the compressed air in the third direction DR3 when the pad PAD is moved in the third direction DR3 to be spaced apart from the glass GLS.

However, the opening portions OP may be defined in the pad PAD according to an embodiment of the invention. Referring to FIG. 8F, when the pad PAD presses the glass GLS, the air inside the dummy groove DGR may be discharged to the outside of the dummy groove DGR through the opening portions OP (dotted-line arrows in FIG. 8F). Accordingly, even when the pad PAD is moved in the third direction DR3, in a direction away from the underlying combined structure, the glass GLS may be secured within an accommodation groove AGR of the jig JG.

The pad PAD may be removed from the glass GLS (FIG. 8G), and the ink INK may be disposed on the rear surface BWM of the glass GLS. The ink INK disposed on the rear surface BWM of the glass GLS may be cured to form the bezel pattern BZ. The bezel pattern BZ may be formed on the glass GLS to manufacture a window WM.

Referring to the structures in FIGS. 6 and 8E, the window WM having the bezel pattern BZ, and a display module DM facing the window WM, may be bonded to each other in a method for providing the electronic device ED. The window WM and the display module DM may be bonded to each other through an adhesive. The window WM and the display module DM bonded to each other may be accommodated in a case EDC. Accordingly, an electronic device ED may be manufactured.

According to the embodiment of the invention, when the pad PAD presses the glass GLS, the ink INK adhered to the protrusion surface PPL may be transferred and adhered to the glass GLS at an area of the glass GLS corresponding to the bezel pattern BZ (or the non-transmission area NTA). Accordingly, the force applied to the glass GLS by the pad PAD in a method of providing the window WM, may be decreased. Thus, the damage to the glass GLS may be reduced or effectively prevented.

The protrusion surface PPL which surrounds the bottom surface BWM of the pad PAD may overlap the outer edge of the glass, and the bottom surface BWM may not come into contact with the glass GLS. Accordingly, the surface area of the glass GLS to come into contact with portions of a lower surface of the pad PAD may be minimized. Thus, contamination of the glass GLS by foreign matter from the lower surface of the pad PAD may be reduced or effectively prevented.

The air inside the dummy groove DGR of the pad PAD may flow to the outside the pad PAD through the hole passing through a thickness of the pad PAD. Accordingly, when the pad PAD is removed from the glass GLS having the transferred ink thereon, the compressed air may prevent the glass GLS (or the transferred ink( from being moved along with the pad PAD and detached from the glass GLS.

In one or more embodiments, to prevent damage or contamination to a target (glass) body of a window WM during transferring bezel pattern ink from an ink pad to the target body, the bezel pattern ink is temporarily adhered to a deformable surface of the ink pad, only at an inner side of the deformable surface. Deformation of the ink pad against the target body disposes only the bezel pattern ink overlapping the target body, together with disposing the deformable surface at both the inner and outer sides to be non-contacting the target body. The ink pad minimizes the lower surfaces in contact with the target body by the deformable surface protruded further than other lower surfaces of the ink pad which face the target body/jig combined structure (e.g., a lower surface at the bottom surface BPL which defines the dummy groove DGR. ), The ink pad minimizes undesirable movement of the target body/bezel pattern ink transferred to the target body by air in the dummy groove DGR which is pressed against the ink pad, by venting the air through the ink pad to outside thereof (e.g., in a direction away from the target body, at the pad opening).

In an embodiment, a method for providing an electronic device ED includes disposing a glass body of a window WM in a jig JG, the glass body including a light transmission area TA of the electronic device ED, and a non-transmission area NTA of the electronic device ED which is adjacent to the light transmission area TA, providing a pad PAD including a pressing part PSP at which an ink INK is adhered to the pad PAD and from which the ink INK is transferred from the pad PAD to the glass body, where the pressing part PSP includes a bottom surface BPL and a protrusion (at PL2) which extends from the bottom surface BPL in a direction away from the bottom surface BPL, the protrusion defining a protrusion surface PPL which is spaced apart from the bottom surface BPL in the direction away from the bottom surface BPL, the ink INK being adhered to the pad PAD at the protrusion surface PPL, transferring the ink INK from the pressing part PSP to the non-transmission area NTA of the glass body by pressing the pad PAD having the ink adhered thereto to the glass body, to form a bezel pattern BZ of the window WM.

The method may further include bonding the window WM having the bezel pattern BZ to a display module DM of the electronic device ED and accommodating the window WM which is bonded to the display module DM, in a case EDC of the electronic device ED.

The protrusion surface PPL of the protrusion may have a convexly curved surface at a distal end of the pressing part PSP. In the method, the jig JG and the glass body therein together may form a combined structure, the pressing of the pad PAD to the glass body may include the distal end of the pressing part PSP initially contacting the combined structure at a reference point SP of the protrusion surface PPL. The convexly curved surface of the protrusion surface PPL may include relative to the reference point SP a first surface PL1 at an inner side of the pressing part PSP which is closest to the glass body in a direction along the combined structure; and a second surface PL2 at an outer side of the pressing part PSP which is further from the glass body than the first surface PL1 is from the glass body in the direction along the combined structure.

Referring to FIGS. 8A-8C, for example, the providing of the pad PAD may further include adhering the ink INK to the protrusion surface PPL at the first surface PL1 of the convexly curved surface, and exposing a remainder of the protrusion to outside of the ink INK.

Referring to FIGS. 8D to 8F, for example, the pressing of the pad PAD to the glass body may further include deforming the distal end of the pressing part PSP to contact both the reference point SP and the first surface PL1 of the protrusion surface PPL with the non-transmission area NTA of the glass body. The deforming of the distal end of the pressing part PSP may include the second surface PL2 not contacting the glass body. The deforming of the distal end may include the bottom surface BPL being spaced apart from the glass body along a thickness direction of the combined structure (e.g., along the third direction DR3).

The pad may further include a body part SPP extended from the pressing part PSP in a direction away from the protrusion, and the body part SPP and the pressing part PSP may have an opening defined extended through the body part SPP and the pressing part PSP.

The pressing part PSP may include a first thickness portion (at PT1) including the bottom surface BPL, and a second thickness portion PT2 extending from an edge of the first thickness portion in the direction away from the bottom surface BPL, the second thickness portion having a rectangular frame shape extended around the edge of the first thickness portion and defining the protrusion of the pressing part PSP.

In an embodiment, a pad printing device for providing a bezel pattern BZ of an electronic device ED includes a mold MD having an ink groove IS defined therein and a bezel ink which is in the ink groove IS, a jig JG having an accommodation groove AGR defined therein, the accommodation groove AGR configured to receive a glass body of a window WM of the electronic device ED, and a pad PAD moveable relative to the jig JG and the mold MD. The pad PAD includes a body part SPP, a pressing part PSP extending from the body part SPP in a direction away from the body part SPP to define a dummy groove DGR of the pad PAD which is open in the direction away from the body part SPP, the pressing part PSP including a lower surface (BPL together with PPL) to which the bezel ink from the ink groove IS is adhered and from which the bezel ink is transferred from the pad PAD to a bezel pattern area of the glass body of the window WM, and an opening extended through the body part SPP and the pressing part PSP, the opening connecting the dummy groove DGR to outside the pad PAD.

The lower surface may include a bottom surface BPL and a protrusion (at PT2) which extends from the bottom surface BPL in a direction away from the bottom surface BPL, the protrusion defining a protrusion surface PPL which is spaced apart from the bottom surface BPL in the direction away from the bottom surface BPL, and the bezel ink being adhered to the pad PAD at the protrusion surface PPL.

An electronic device 1000 according to an embodiment of the present disclosure includes a display device DD and a power module 1040 which supplies power to the display device DD. The display device DD includes a substrate, a via insulating layer on the substrate, a first pixel electrode on the via insulating layer, a second pixel electrode on the first pixel electrode and having an upper surface which is flat, and a third pixel electrode on the second pixel electrode.

The display device DD (or display module DM) according to embodiments of the present disclosure may be applied to various electronic devices. An electronic device 1000 according to an embodiment of the present disclosure may include the display device DD (or the display module DM) described above, and may further include a module or device having additional functions in addition to the display device DD (or the display module DM).

FIG. 14 is a block diagram illustrating an electronic device 1000 according to an embodiment of the present disclosure.

Referring to FIG. 14, an electronic device 1000 may include a display module 1010, a processor 1020, a memory 1030, and a power module 1040.

The processor 1020 may include at least one of a central processing unit (CPU), an application processor (AP), a graphic processing unit (GPU), a communication processor (CP), an image signal processor (ISP), and a controller.

The memory 1030 may store data information necessary for an operation of the processor 1020 or the display module 1010. When the processor 1020 executes an application stored in the memory 1030, an image data signal and/or an input control signal may be transmitted to the display module 1010, and the display module 1010 may process the received signal and output image information through a display screen.

The power module 1040 may include a power supply module such as a power adapter, a battery device, or the like and a power conversion module which converts power supplied by the power supply module to generate power necessary for an operation of the electronic device 1000.

At least one of the components of the electronic device 1000 described above may be included in the display device DD (or the display module DM) according to embodiments described above. In addition, some of individual modules functionally included in one module may be included in the display device DD (or the display module DM), and others may be provided separately from the display device DD (or the display module DM). For example, the display device may include the display module 1010, and the processor 1020, the memory 1030, and the power module 1040 may be provided in form of other devices in the electronic device 1000 other than the display device DD (or the display module DM).

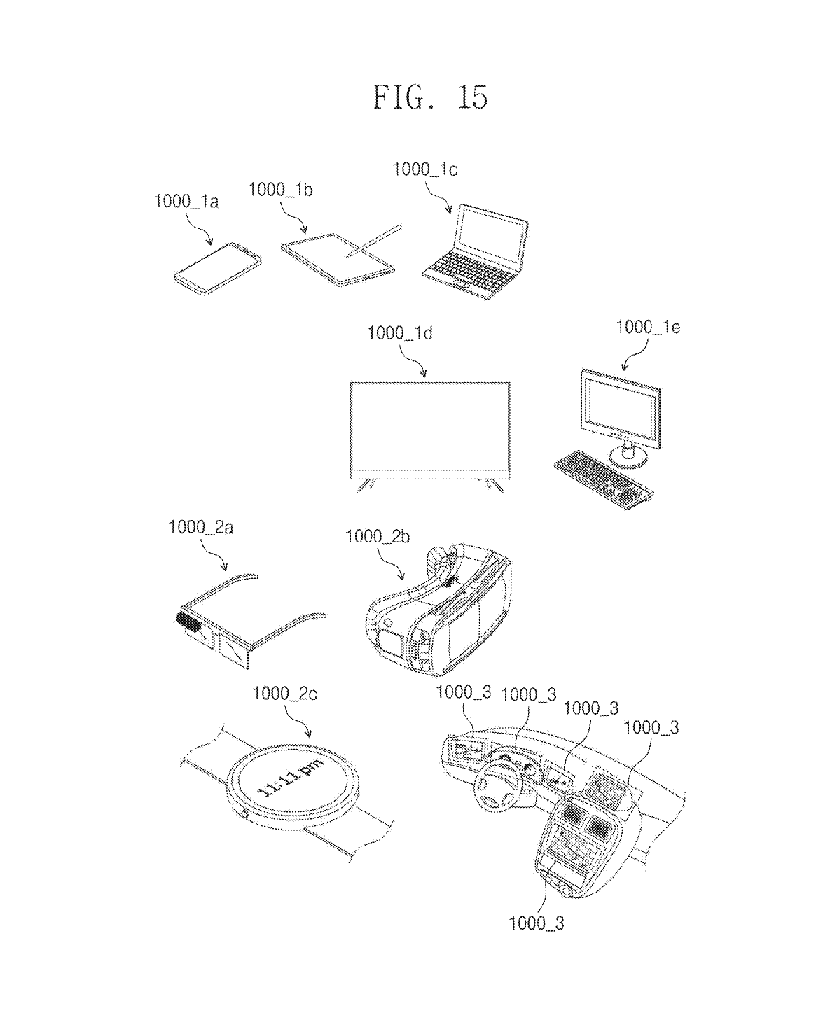

FIG. 15 is a schematic view of electronic devices according to embodiments of the present disclosure.

Referring to FIG. 15, various electronic devices to which the display device according to embodiments of the present disclosure are applied may include not only an image display electronic device, but also a wearable electronic device including a display device (or a display module), a vehicle electronic device 1000_3 including a display module, or the like. The image display electronic device may be a smartphone 1000_1a, a tablet PC 1000_1b, a laptop 1000_1c, a TV 1000_1d, a desk monitor 1000_1e, or the like. The wearable electronic device may be smart glasses 1000_2a, a head mounted display 1000_2b, a smart watch 1000_2c, or the like. The vehicle electronic device 1000_3 may be a center information display (CID) disposed on a dashboard and center fascia of a vehicle, a room mirror display, or the like.

In the above, description has been made with reference to embodiments of the invention, but those skilled or of ordinary skill in the art may understand that various modifications and changes may be made to the invention insofar as such modifications and changes do not depart from the spirit and technical scope of the invention set forth in the claims to be described later. Therefore, the technical scope of the invention is not to be limited to the contents stated in the detailed description of the specification, but should be determined by the claims.

What is claimed is:

1. A method for providing a window of an electronic device, the method comprising:
disposing a glass body of the window in a jig, the glass body comprising a light transmission area of the electronic device, and a non-transmission area of the electronic device which is adjacent to the light transmission area;
providing a pad comprising:
a pressing part at which an ink is adhered to the pad and from which the ink is transferred from the pad to the glass body;
the pressing part comprising a bottom surface and a protrusion which extends from the bottom surface in a direction away from the bottom surface; and
the protrusion defining a protrusion surface which is spaced apart from the bottom surface in the direction away from the bottom surface, the ink being adhered to the pad at the protrusion surface; and
transferring the ink from the pressing part to the non-transmission area of the glass body by pressing the pad having the ink adhered thereto to the glass body, to form a bezel pattern of the window.

2. The method of claim 1, wherein the protrusion surface of the protrusion comprises a convexly curved surface at a distal end of the pressing part.

3. The method of claim 2, wherein
the jig and the glass body therein together form a combined structure;
the pressing of the pad to the glass body includes the distal end of the pressing part initially contacting the combined structure at a reference point of the protrusion surface; and
the convexly curved surface of the protrusion surface comprises relative to the reference point:
a first surface at an inner side of the pressing part which is closest to the glass body in a direction along the combined structure; and
a second surface at an outer side of the pressing part which is further from the glass body than the first surface is from the glass body in the direction along the combined structure.

4. The method of claim 3, wherein the providing of the pad further includes:
adhering the ink to the protrusion surface at the first surface of the convexly curved surface, and
exposing a remainder of the protrusion to outside of the ink.

5. The method of claim 3, wherein the pressing of the pad to the glass body further includes deforming the distal end of the pressing part to contact both the reference point and the first surface of the protrusion surface with the non-transmission area of the glass body.

6. The method of claim 5, wherein the deforming of the distal end of the pressing part includes the second surface not contacting the glass body.

7. The method of claim 5, wherein the deforming of the distal end includes the bottom surface being spaced apart from the glass body along a thickness direction of the combined structure.

8. The method of claim 1, wherein
the jig has an accommodation groove defined therein;
the glass body is in the accommodation groove and has an outer edge facing an inner edge of the jig at the accommodation groove; and
the pressing of the pad to the glass body includes:
the protrusion surface of the pressing part overlapping the outer edge of the glass body, and
the bottom surface of the pressing part being spaced apart from the glass body along a thickness direction of the pad.

9. The method of claim 1, wherein the pad further comprises:
a body part extended from the pressing part in a direction away from the protrusion; and
the body part and the pressing part having an opening defined extended through the body part and the pressing part.

10. The method of claim 1, wherein the pressing part comprises:
a first thickness portion including the bottom surface; and
a second thickness portion extending from an edge of the first thickness portion in the direction away from the bottom surface, the second thickness portion having a rectangular frame shape extended around the edge of the first thickness portion and defining the protrusion of the pressing part.

11. A method for providing an electronic device, the method comprising:
providing a glass body of a window of the electronic device, in a jig;
providing a pad having an ink adhered to a pressing part of the pad, the pressing part comprising:
a bottom surface and a protrusion which extends from the bottom surface in a direction away from the bottom surface; and
the protrusion defining a protrusion surface which is curved and spaced apart from the bottom surface in the direction away from the bottom surface, the ink being adhered to the pad at the protrusion surface; and
transferring the ink from the pressing part to an outer edge of the glass body by pressing the pad having the ink adhered thereto to the glass body, to form a bezel pattern of the window.

12. The method of claim 11, wherein
the jig and the glass body therein together form a combined structure;
the pressing of the pad to the glass body includes the protrusion surface initially contacting the combined structure at a reference point of the protrusion surface; and
the protrusion surface is convexly curved and comprises relative to the reference point:
a first surface at an inner side of the pressing part which is closest to the glass body in a direction along the combined structure; and
a second surface at an outer side of the pressing part which is further from the glass body than the first surface is from the glass body in the direction along the combined structure.

13. The method of claim 12, wherein the providing of the pad includes:
adhering the ink to the protrusion surface at the reference point and the first surface, and
exposing a remainder of the protrusion to outside of the ink.

14. The method of claim 12, wherein
the protrusion surface is defined at a distal end of the pressing part; and
the pressing of the pad to the glass body further includes deforming the distal end of the pressing part to contact both the reference point and the first surface with the glass body at the outer edge thereof.

15. The method of claim 11, wherein
the bottom surface together with the protrusion surface provide a dummy groove of the pad which is open in a direction away from the bottom surface, and
the pad has an opening extended through a thickness of the pressing part, the opening connecting the dummy groove to outside the pad.

16. The method of claim 11, further comprising:
bonding the window having the bezel pattern to a display module of the electronic device; and
accommodating the window which is bonded to the display module, in a case of the electronic device.

17. A pad printing device for providing a bezel pattern of an electronic device, the pad printing device comprising:
a mold having an ink groove defined therein and a bezel ink which is in the ink groove;
a jig having an accommodation groove defined therein, the accommodation groove configured to receive a glass body of a window of the electronic device; and
a pad moveable relative to the jig and the mold, the pad comprising:
a body part;
a pressing part extending from the body part in a direction away from the body part to define a dummy groove of the pad which is open in the direction away from the body part;
the pressing part comprising a lower surface to which the bezel ink from the ink groove is adhered and from which the bezel ink is transferred from the pad to a bezel pattern area of the glass body of the window; and
an opening extended through the body part and the pressing part, the opening connecting the dummy groove to outside the pad.

18. The pad printing device of claim 17, wherein the lower surface of the pressing part comprises:
a bottom surface and a protrusion which extends from the bottom surface in a direction away from the bottom surface;
the protrusion defining a protrusion surface which is spaced apart from the bottom surface in the direction away from the bottom surface, and the bezel ink being adhered to the pad at the protrusion surface.

19. The pad printing device of claim 18, wherein the protrusion surface has a convexly curved surface at a distal end of the pressing part.

20. The pad printing device of claim 19, wherein
the jig and the glass body which is in the accommodation groove of the jig together form a combined structure;
pressing of the pad to the glass body includes the distal end of the pressing part initially contacting the combined structure at a reference point of the protrusion surface; and
the convexly curved surface of the protrusion surface comprises relative to the reference point:
a first surface at an inner side of the pressing part which is closest to the glass body in a direction along the combined structure; and
a second surface at an outer side of the pressing part which is further from the glass body than the first surface is from the glass body in the direction along the combined structure.
